(19) United States
(12) Patent Application Publication
(10) Pub. No.: US 2026/0238233 A1
(43) Pub. Date: Aug. 13, 2026

(54) Soft-Decision Block Decoder

(71) Applicant: Digital Voice Systems, Inc., Westford, MA (US)

(72) Inventors: Thomas Clark, Westford, MA (US); John C. Hardwick, Acton, MA (US)

(21) Appl. No.: 19/052,852

(22) Filed: Feb. 13, 2025

(51) Int. Cl. H03M 13/45; H03M 13/11

(52) U.S. Cl. CPC H03M 13/451; H03M 13/1108; H03M 13/1111

(57) ABSTRACT

A method of soft-decision decoding a block code implemented by a soft-decision block decoder includes receiving a soft-decision codeword encoded using the block code; hard-decision decoding the most significant codeword that is a hard-decision representation of the soft-decision codeword to obtain a corrected codeword; identifying the number of bits flipped in the corrected codeword and bit positions of the flipped bits based on a difference between the most significant codeword and the corrected codeword; generating a set of codeword candidates based on the number of flipped bits and the bit positions of the flipped bits; determining a soft-decision distance between each codeword candidate and the soft-decision codeword; and identifying a codeword candidate from among the set of codeword candidates that has the lowest soft-decision distance as an output of the soft-decision block decoder.

### TECHNICAL FIELD

This disclosure relates generally to digital communications.

### BACKGROUND

Digital communication systems transmit digital information. For example, digital voice communication systems, such as mobile radio and cellular telephony, transmit voice as digital data. In such digital voice communication systems, an encoder converts an analog voice signal from a microphone into a digital waveform using an analog-to-digital converter to produce a sequence of voice samples that are processed for further use. Since transmission bandwidth is limited in these systems, the processing uses compression of the voice data to reduce the data to be transmitted. After transmission, a decoder reverses the encoding process and converts the low-rate voice bit stream back into a sequence of voice samples that are suitable for playback via a digital-to-analog converter and a loudspeaker or for other processing.

A soft-decision block decoder is a component in digital communication systems that is designed to decode received data that has been transmitted over a noisy channel using soft-decision inputs instead of hard-decision bits. It may be used with an error-correcting block code, such as a Golay block code or a Hamming block code.

A soft-decision block decoder for high-speed communication systems is usually implemented in digital hardware, such as Field-Programmable Gate Arrays (FPGAs), Application-Specific Integrated Circuits (ASICs), a processor, or a microcontroller. The soft-decision block decoder also may be implemented in software.

### SUMMARY

Techniques are provided for soft-decision decoding a block code that can achieve performance close to Maximum Likelihood (ML) decoding while significantly decreasing computational complexity. The techniques can be applied in various communication and signal processing systems where error correction is required, particularly in noisy environments or scenarios requiring high reliability. For example, the techniques can be applied in wireless communication, such as cellular network technology (e.g., 4G Long Term Evolution (LTE), 5G), Wi-Fi, digital mobile radio systems, for example, a P25, DMR, dPMR, Next Generation Digital Narrowband (NXDN™), Mototrbo™, etc. The techniques can also be applied in satellite and space communication, multimedia broadcasting, automotive and vehicle-to-everything (V2X) communication.

In one general aspect, a method of soft-decision decoding a block code implemented by a soft-decision block decoder includes receiving a soft-decision codeword encoded using the block code. The soft-decision codeword includes codewords that at least include a most significant codeword and a least significant codeword. The most significant codeword is a hard-decision representation of the soft-decision codeword, and is hard-decision decoded to obtain a corrected codeword. The number of bits flipped in the corrected codeword and bit positions of the flipped bits are identified based on a difference between the most significant codeword and the corrected codeword. A set of codeword candidates are generated based on the number of flipped bits and the bit positions of the flipped bits. The set of codeword candidates are those closest to the corrected codeword, where a distance between each candidate codeword and the corrected codeword is less than a first threshold, and a distance between each candidate codeword and the most significant codeword is less than a second threshold. A soft-decision distance between each codeword candidate and the soft-decision codeword is determined. A codeword candidate from among the set of codeword candidates that has the lowest soft-decision distance is identified as an output of the soft-decision block decoder.

Implementations may include one or more of the following features. For example, the most significant codeword may include the most significant bit (MSB) of each soft-decision bit in the soft-decision codeword.

The number of the flipped bits may be associated with a type of the block code. The type of the block code may be a Golay (23,12) code, a Golay (24,12) code or a Hamming code.

Generating the set of codeword candidates may include generating one or more sets of masks based on the number of flipped bits and a type of the block code; and applying the one or more sets of masks to the most significant codeword to obtain the set of codeword candidates.

Applying each set of masks to the most significant codeword may include Exclusive-ORing (XORing) each set of masks with the set of codeword candidates.

Determining the soft-decision distance may include computing a Hamming distance between each of the plurality of codewords and a candidate codeword and computing a weighted sum of the Hamming distances. Each of the plurality of codewords may be associated with a different weight.

A weight associated with the least significant codeword may be one, and a weight associated with a successively more significant codeword may be twice a weight associated with an immediately previous codeword.

The method may further include identifying at least two identical codewords from the plurality of codewords; summing weights associated with the two identical codewords; and eliminating at least one identical codeword, so that no codewords are identical in the plurality of codewords.

The first threshold may be larger than the second threshold.

In another general aspect, a method of soft-decision decoding a block code implemented by a soft-decision block decoder includes receiving a soft-decision codeword encoded using the block code. The soft-decision codeword includes codewords that at least include a most significant codeword and a least significant codeword. The most significant codeword is a hard-decision representation of the soft-decision codeword and is hard-decision decoded to obtain a corrected codeword. A soft-decision distance between the corrected codeword and the soft-decision codeword is determined. The corrected codeword is determined as an output of the soft-decision block decoder based on the soft-decision distance between the corrected codeword and the soft-decision codeword being less than or equal to a particular threshold.

The techniques for soft-decision decoding of a block code discussed above and described in more detail below may be implemented by a soft-decision block decoder or a speech decoder, such as a multiband excitation (MBE) decoder. The soft-decision block decoder or speech decoder may be included in, for example, a wireless communication device, such as a handset, a mobile radio device, a base station, or a console.

The details of one or more implementations of the subject matter are set forth in the accompanying drawings and the description below. Other features, aspects, and advantages of the subject matter will become apparent from the description, the drawings, and the claims.

### BRIEF DESCRIPTION OF THE DRAWINGS

FIG. 1 illustrates an example soft-decision block decoder.

FIG. 2 is a table illustrating the number of codewords with respect to the distance between W and other valid codewords.

FIG. 3 is a diagram illustrating the distance from codeword W to

$${C}_{k}^{7} ( W ) and {C}_{k}^{8} ( W ) .$$

FIG. 4 is a diagram illustrating M⁷, subsets M⁷[a], M⁷[b] and M⁷[c], and intersections among subsets M⁷[a], M⁷[b] and M⁷[c].

FIG. 5 is a diagram illustrating M⁸, subsets M⁸[a], M⁸[b] and M⁸[c], and intersections among subsets M⁸[a], M⁸[b] and M⁸[c].

FIG. 6 is a table illustrating I⁷ indices to

$${M}_{i , j}^{7}$$

used to compute subsets M⁷[a, b].

FIG. 7 is a table illustrating J⁷ indices to

$${M}_{i , j}^{7}$$

used to compute subsets M⁷[a, b].

FIG. 8 is a table illustrating I⁸ indices to

$${M}_{i , j}^{8}$$

used to compute subsets M⁸[a, b].

FIG. 9 is a table illustrating J⁸ indices to

$${M}_{i , j}^{8}$$

used to compute subsets M⁸[a, b].

FIG. 10 is a table illustrating two alternate ways I^{7p} and I^{7d} to store I⁷.

FIG. 11 is a diagram illustrating subsets that can be derived from intersections of M⁷[a], M⁷[b] and M⁷[c].

FIG. 12 is a table summarizing the subsets that are shown in FIG. 11.

FIG. 13 is a diagram illustrating subsets that can be derived from intersections of M⁸[a], M⁸[b] and M⁸[c].

FIG. 14 is a table summarizing the subsets of M⁸.

FIG. 15 is a table illustrating Hamming (15,11) code distance distribution properties.

FIG. 16 is a table illustrating the computation of a soft-decision distance between R and W when B=4 and L=8.

FIG. 17 is a table illustrating the number of codewords that have various distances for each value of f.

FIG. 18 is a table illustrating a summary of the subsets of masks used to compute set m, the length of each subset, and the distances corresponding to each subset.

FIG. 19 is a flow chart of a process of soft-decision decoding a block code.

FIG. 20 is a block diagram of a vocoder.

Like reference symbols in the various drawings indicate like elements.

### DETAILED DESCRIPTION

The described techniques provide methods for soft-decision decoding of a block code that can achieve performance close to Maximum Likelihood (ML) decoding while keeping computational complexity much lower. The methods generate a subset of valid codewords that have the lowest hard-decision distances from the received soft-decision codeword. The soft-decision distance between each of the codewords in the subset and the received soft-decision codeword is then evaluated, and the codeword from the subset that has the minimum soft-decision distance from the received soft-decision codeword is chosen as the output codeword. An efficient method of computing soft-decision distances using a weighted sum of Hamming distances is utilized. Various tradeoffs between complexity and performance are provided. Methods for decoding Golay (23,12), Golay (24,12), and Hamming (15,11) block codes are provided. In some implementations, the methods for decoding Golay (23,12), Golay (24,12), and Hamming (15,11) block codes may be adapted for decoding other block codes.

A block code is an error-correcting code that is used to reduce or eliminate bit errors in the data that it protects. The block code takes N bits of input data and adds redundancy to produce L bits of output data, where L>N. The output data is in the form of L-bit blocks called codewords. A block coder takes the N source bits and generates an L-bit codeword. After coding, the codeword passes through a communication channel. Noise or interference in the communication channel may introduce errors, such that the received codeword can be different from the codeword that was transmitted. A block decoder takes the received codeword and uses the redundancy to try to recover the original input data. The block decoder may receive a codeword that is not a valid codeword that could be produced by the block coder. The block decoder attempts to determine a valid codeword that is closest to the codeword that was received, and the received codeword is replaced by the closest valid codeword determined by the block decoder. The distance between each valid codeword (which may have been transmitted) and the received codeword can be evaluated. A Hamming distance is the number of bits that are different between two codewords. The block decoder aims to determine the valid codeword that has the smallest Hamming distance from the received codeword. Many different block codes exist with various block lengths and error-correcting capabilities. Some methods of this disclosure can be applied to block codes in general. In some implementations, this disclosure provides methods for decoding three different block codes, e.g., a Golay (23,12) code (L=23), a Golay (24,12) code (L=24), and a Hamming (15,11) code (L=15).

A block decoder uses the added redundancy in the block code to correct errors in the data. The received codeword is represented using L bits. In some implementations, every received bit is a binary “0” or “1”. The block decoder that decodes codewords including such binary data can be referred to as a hard-decision block decoder. In some implementations of communication systems, the received bits may be received with varying degrees of confidence. In such communication systems, every received bit is represented as an integer in the range from 0 to 2^{B}-1, such that a received bit value of 0 represents high confidence that the received bit is “0” and a received bit value of 2^{B}-1 represents high confidence that the received bit is “1”. A received bit value in between the two extremes (“0” and “2^{B}-1”) represents that the bit was received with reduced confidence. A received bit value close to the midpoint of the range [0, 2^{B}-1] has very low confidence. Values in the range [0, 2^{B}-1] can be represented using a B-bit integer. This input format is referred to as the B-bit soft-decision input format. For example, with a 4-bit soft-decision input format, there are 24=16 possible input levels {0, 1, 2, . . . , 7, 8, . . . , 14, 15}, where 0 is the most confident “0”, 7 is the least confident “0”, 8 is the least confident “1”, and 15 is the most confident “1”. When B is 1, the number of possible input levels for each bit reduces to 2 and the possible bit representations are {0, 1}. This binary representation is referred to as a hard-decision format that is a specific type (when B=1) of the soft-decision input format.

When the block decoder receives bits in B-bit soft-decision input format, the block decoder is referred to as a B-bit soft-decision block decoder. The soft-decision input format has a higher resolution for the distance between the received codeword and every possible codeword that might have been transmitted. As to a hard-decision block decoder, all the distances evaluated are Hamming distances. As to the soft-decision block decoder, the distances are formed using a weighted sum of Hamming distances. A received B-bit soft-decision codeword, R, having a length, L, includes a total of L×B bits of information. Each soft-decision codeword may be represented as a series of L B-bit soft-decision bits, or alternatively as a series of B L-bit codewords. The received bits may be arranged into a matrix including L columns, with each column having B bits, or a matrix including B rows, with each row having L bits. The methods described herein assume that the soft-decision codewords are received as a series of B L-bit codewords, R_{b} for 0≤b<B, where codeword R_{B-1} is a codeword obtained by packing the MSB (bit B−1) of each received bit into an L-bit codeword. Similarly, R_{B-2} is a codeword obtained by packing bit B−2 of each received soft-decision bit into an L-bit codeword. This continues until finally R₀ is a codeword obtained by packing the LSB (bit 0) of each received bit into an L-bit codeword.

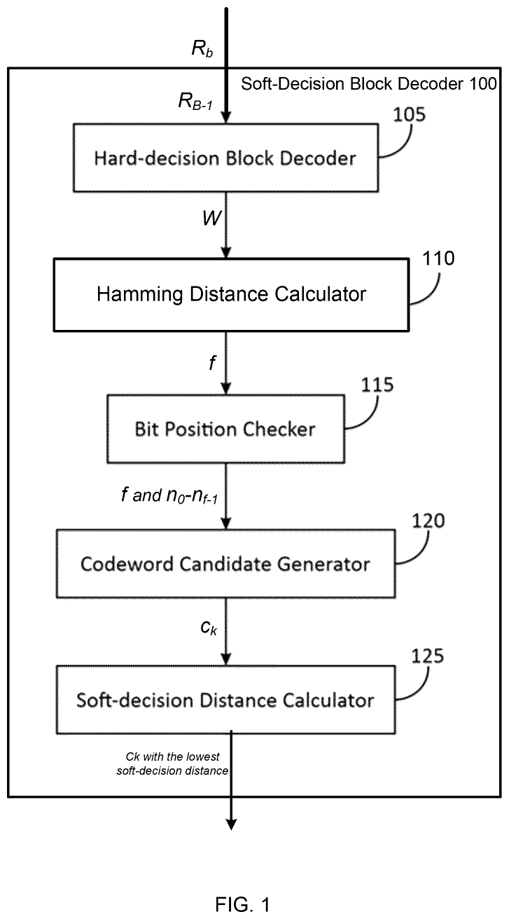

B-bit soft-decision decoding methods are described, which decode Golay (23,12) block code, Golay (24,12) block code, or Hamming (15.11) block code. FIG. 1 illustrates an example soft-decision block decoder 100. The soft-decision block decoder 100 includes hard-decision block decoder 105, Hamming distance calculator 110, bit position checker 115, codeword candidate generator 120, and soft-decision distance calculator 125. A received B-bit soft-decision codeword, R, denoted by R_{b} for 0≤b<B is input to the soft-decision block decoder 100. The length of each codeword in R_{b} is L bits. For example, the hard-decision block decoder 105 decodes codeword R_{B-1} to generate a codeword, W, which minimizes the Hamming distance between R_{B-1} and W. The codeword W is within the set of possible valid codewords that could have been transmitted by the encoder. Hamming Distance calculator 110 computes a Hamming distance between W and R_{B-1} and stores the Hamming distance as variable f. The hard-decision block decoder 105 may flip various bits to generate W from R_{B-1}. The hard-decision block decoder 105 can flip a limited number of bits. For instance, a Golay (23,12) block decoder can flip between 0 and 3 bits, a Golay (24,12) decoder can flip between 0 and 4 bits, and a Hamming (15,11) decoder can flip either 0 or 1 bits. Bit position checker 115 records the bit positions that were flipped by the hard-decision block decoder 105 to generate W from R_{B-1}. Each bit position is an integer between 0 and L−1 (inclusive), and the number of bit positions that were flipped is f. The bit positions are denoted by n₀ through n_{f-1}. Codeword candidate generator 120 is used to generate a subset of codewords that are closest to codeword W. The candidates (the subset of codewords) are generated based on f and n₀ through n_{f-1}. The codeword candidate generator 120 is used to reduce the number of codewords to a small subset of all the possible codewords that can be represented by the block code. Reducing the number of codewords to a small subset reduces the complexity of the soft-decision block decoder 100. The codeword candidates are denoted by cₖ for 0≤k<K, where K is much lower than the number of unique codewords that might have been transmitted. For example, K for the Golay (23,12) soft-decision block decoder is 78 or less, whereas the number of unique Golay codes is 4096. After generating a set of codeword candidates, a distance for each candidate is calculated by a soft-decision distance calculator 125. The distance between each codeword candidate, cₖ, and the received codeword, R_{b} for 0≤b<B, is evaluated. The candidate with the lowest soft-decision distance is determined to be the most likely transmitted codeword and thus is the output of the soft-decision block decoder 100.

In some implementations, a Maximum Likelihood (ML) Decoder is a soft-decision decoder that evaluates the distance between the received codeword and every possible codeword that might have been transmitted. As to Golay (23,12), the total number of unique codewords is 4096. Although the ML decoder produces the theoretical best decoder result, it comes at the cost of high complexity. The soft-decision Golay (23,12) decoder (an example of soft-decision block decoder 100) reduces the number of codeword candidates that are evaluated to 78 or fewer, which represents a complexity reduction of more than 98 percent relative to the ML Decoder. The soft-decision Golay (23,12) decoder can achieve this complexity reduction with negligible impact on decoding performance. Similarly, the soft-decision block decoder 100 can result in complexity reductions for soft-decision decoding of Golay (24,12) and Hamming (15,11) codes. The soft-decision block decoder 100 can also reduce the complexity for other block codes.

### Soft-Decision Golay Decoder

The soft-decision Golay (23,12) decoder and the soft-decision Golay (24,12) decoder each make use of some properties of a Golay code. For both the Golay (23,12) code and Golay (24,12) code, every codeword transmitted is chosen from a set of 4096 possible codes. As to a Golay (23,12) code, the minimum distance between two codewords is 7, which indicates that any codeword differs from all other possible codewords by at least 7 bits. Similarly, the minimum distance of the Golay (24,12) code is 8.

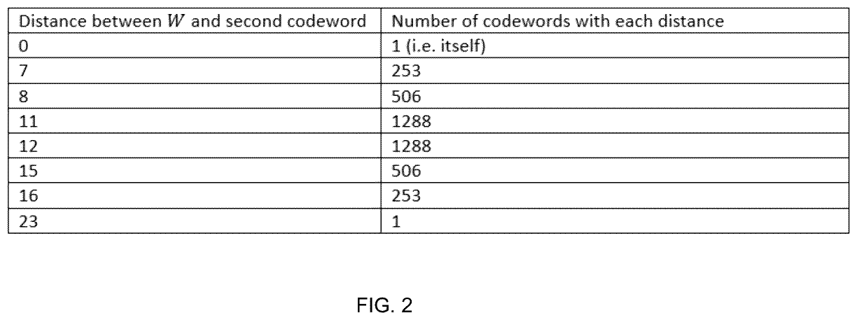

In some implementations, W is a valid 23-bit Golay (23,12) codeword. Accordingly, there are 253 codewords that have a distance of 7 from W, and there are 506 codewords that have a distance of 8 from W. Since the minimum distance is 7, there are no other codewords (other than W itself) that have a distance less than 7. In addition, there are no valid codewords that have distance 9 or 10 (a property of the Golay (23,12) code). The table in FIG. 2 summarizes the distances of 4096 valid codewords from codeword W. FIG. 2 is a table illustrating the number of codewords with respect to the distance between W and other valid codewords.

The matrix, G⁷ as defined below can be used to generate 253 valid Golay (23,12) codewords that have a distance of 7 from another valid codeword, W.

$${G}^{7} = [ \begin{matrix}0 & 0 & 0 & 0 & 0 & 0 & 0 & 0 & 0 & 0 & 0 & 1 & 1 & 0 & 0 & 0 & 1 & 1 & 1 & 0 & 1 & 0 & 1 \\ 0 & 0 & 0 & 0 & 0 & 0 & 0 & 0 & 0 & 1 & 0 & 0 & 1 & 0 & 1 & 0 & 1 & 0 & 0 & 1 & 0 & 1 & 1 \\ 0 & 0 & 0 & 0 & 0 & 0 & 0 & 0 & 1 & 0 & 1 & 1 & 1 & 1 & 0 & 0 & 0 & 0 & 0 & 1 & 0 & 0 & 1 \\ 0 & 0 & 0 & 0 & 0 & 0 & 0 & 1 & 0 & 0 & 0 & 0 & 0 & 0 & 1 & 1 & 0 & 1 & 1 & 0 & 0 & 1 & 1 \\ 0 & 0 & 0 & 0 & 0 & 0 & 0 & 1 & 0 & 1 & 0 & 1 & 0 & 0 & 0 & 1 & 0 & 0 & 0 & 1 & 1 & 0 & 1 \\ 0 & 0 & 0 & 0 & 0 & 0 & 1 & 0 & 1 & 0 & 0 & 0 & 1 & 0 & 1 & 1 & 0 & 0 & 0 & 0 & 1 & 0 & 1 \\ 0 & 0 & 0 & 0 & 0 & 0 & 1 & 1 & 1 & 0 & 0 & 1 & 0 & 0 & 0 & 0 & 1 & 0 & 0 & 0 & 0 & 1 & 1 \\ 0 & 0 & 0 & 0 & 0 & 1 & 0 & 0 & 0 & 0 & 1 & 0 & 0 & 1 & 0 & 0 & 1 & 0 & 1 & 0 & 0 & 1 & 1 \\ 0 & 0 & 0 & 0 & 0 & 1 & 0 & 0 & 1 & 1 & 0 & 1 & 0 & 0 & 1 & 0 & 0 & 0 & 1 & 0 & 0 & 0 & 1 \\ 0 & 0 & 0 & 0 & 0 & 1 & 1 & 0 & 0 & 1 & 0 & 0 & 0 & 0 & 0 & 1 & 1 & 1 & 0 & 0 & 0 & 0 & 1 \\ 0 & 0 & 0 & 0 & 1 & 0 & 0 & 0 & 1 & 1 & 0 & 0 & 0 & 1 & 0 & 0 & 1 & 0 & 0 & 0 & 1 & 0 & 1\end{matrix} ]$$

Where the bits in G⁷ can be packed into eleven 23-bit vectors to form g⁷.

$${ℊ}^{7} = [ \begin{matrix}{ℊ}_{0}^{7} \\ {ℊ}_{1}^{7} \\ {ℊ}_{2}^{7} \\ {ℊ}_{3}^{7} \\ {ℊ}_{4}^{7} \\ {ℊ}_{5}^{7} \\ {ℊ}_{6}^{7} \\ {ℊ}_{7}^{7} \\ {ℊ}_{8}^{7} \\ {ℊ}_{9}^{7} \\ {ℊ}_{10}^{7}\end{matrix} ] = [ \begin{matrix}0 x00c75 \\ 0 x0254b \\ 0 x05e09 \\ 0 x081b3 \\ 0 x0a88d \\ 0 x14585 \\ 0 x1c843 \\ 0 x21253 \\ 0 x26911 \\ 0 x320e1 \\ 0 x46245\end{matrix} ]$$

Where

$${ℊ}_{i}^{7}$$

are referred to as 7-bit roots of the Golay code. Each of the eleven roots has seven bits that are one and sixteen bits that are zero.

If the j^{th} 23-bit rotation of

$${ℊ}_{i}^{7}$$

is denoted as ror23

$$( {ℊ}_{i}^{7} , j ) ,$$

then a set of 253, 23-bit masks,

$${M}_{k}^{7}$$

for 0≤k<253, can be computed according to Equation (1).

$${M}_{k}^{7} = {M}_{i , j}^{7} = r o {r}^{23} ( {ℊ}_{i}^{7} , j )$$

for 0≤i<11, 0≤j<23, where k=23i+j Equation (1)

This set of masks is constant and can be tabularized, such that it can be indexed by both i and j, for computational efficiency. Every mask in

$${M}_{k}^{7}$$

for 0≤K<453 has a Hamming weight of 7. Each member of the set M⁷ is unique. For any valid Golay codeword W, all the valid codewords that have a distance of 7 from W can be generated by applying each of the masks to the codeword W according to equation (2).

$$\begin{matrix}{C}_{k}^{7} ( W ) = W + {M}_{k}^{7} & 0 \leq k < 253\end{matrix} \qquad Equation ( 2 )$$

The addition in the above Equation (2) is binary, such that for each of the 23 bits, the mask is exclusive-ored with the codeword W. Since each of the masks has 7 bits that are one, every member of the set

$${C}_{k}^{7} ( W )$$

differs from W by 7 bits. For any valid Golay codeword, W, there are 253 other valid codewords that have a distance of 7 from W. The codewords can be generated by applying a set of masks to W. There are no valid Golay (23,12) codewords that have a distance between 1 and 6, and thus the generated codewords are the codewords that are closest to W.

The matrix, G⁸, as defined below can be used to generate 506 valid Golay (23,12) codewords that have a distance of 8 from another valid codeword, W.

$${G}^{8} = [ \begin{matrix}0 & 0 & 0 & 0 & 0 & 0 & 0 & 0 & 0 & 0 & 1 & 0 & 1 & 0 & 0 & 1 & 0 & 0 & 1 & 1 & 1 & 1 & 1 \\ 0 & 0 & 0 & 0 & 0 & 0 & 0 & 0 & 0 & 1 & 1 & 1 & 1 & 0 & 1 & 1 & 0 & 1 & 0 & 0 & 0 & 0 & 1 \\ 0 & 0 & 0 & 0 & 0 & 0 & 0 & 0 & 1 & 0 & 0 & 0 & 1 & 1 & 0 & 1 & 1 & 1 & 0 & 0 & 0 & 1 & 1 \\ 0 & 0 & 0 & 0 & 0 & 0 & 1 & 1 & 0 & 0 & 1 & 1 & 0 & 0 & 1 & 0 & 1 & 0 & 1 & 1 & 0 & 0 & 1 \\ 0 & 0 & 0 & 0 & 0 & 0 & 1 & 1 & 0 & 1 & 1 & 0 & 0 & 0 & 0 & 0 & 1 & 1 & 0 & 0 & 1 & 1 & 1 \\ 0 & 0 & 0 & 0 & 0 & 0 & 1 & 1 & 1 & 0 & 0 & 1 & 0 & 1 & 1 & 0 & 0 & 1 & 0 & 0 & 1 & 0 & 1 \\ 0 & 0 & 0 & 0 & 0 & 0 & 1 & 1 & 1 & 1 & 0 & 0 & 0 & 1 & 0 & 0 & 0 & 0 & 1 & 1 & 0 & 1 & 1 \\ 0 & 0 & 0 & 0 & 0 & 0 & 0 & 0 & 0 & 0 & 0 & 1 & 1 & 1 & 1 & 0 & 0 & 0 & 1 & 0 & 0 & 1 & 1 \\ 0 & 0 & 0 & 0 & 0 & 0 & 0 & 0 & 0 & 1 & 0 & 0 & 1 & 1 & 0 & 0 & 0 & 1 & 0 & 1 & 1 & 0 & 1 \\ 0 & 0 & 0 & 0 & 0 & 0 & 0 & 0 & 1 & 1 & 1 & 0 & 1 & 0 & 0 & 0 & 1 & 0 & 1 & 0 & 0 & 0 & 1 \\ 0 & 0 & 0 & 0 & 0 & 0 & 1 & 1 & 0 & 0 & 0 & 0 & 0 & 1 & 0 & 1 & 1 & 0 & 1 & 0 & 1 & 0 & 1 \\ 0 & 0 & 0 & 0 & 0 & 0 & 1 & 1 & 1 & 0 & 1 & 0 & 0 & 0 & 0 & 1 & 0 & 1 & 0 & 1 & 0 & 0 & 1 \\ 0 & 0 & 0 & 0 & 0 & 1 & 0 & 0 & 0 & 0 & 0 & 1 & 0 & 1 & 0 & 1 & 0 & 1 & 1 & 1 & 0 & 0 & 1 \\ 0 & 0 & 0 & 0 & 0 & 1 & 0 & 0 & 0 & 1 & 0 & 0 & 0 & 1 & 1 & 1 & 0 & 0 & 0 & 0 & 1 & 1 & 1 \\ 0 & 0 & 0 & 0 & 0 & 1 & 0 & 0 & 1 & 0 & 1 & 1 & 0 & 0 & 0 & 1 & 1 & 0 & 0 & 0 & 1 & 0 & 1 \\ 0 & 0 & 0 & 0 & 0 & 1 & 1 & 0 & 0 & 0 & 1 & 0 & 0 & 0 & 1 & 0 & 0 & 1 & 1 & 0 & 1 & 0 & 1 \\ 0 & 0 & 0 & 0 & 0 & 1 & 1 & 0 & 1 & 0 & 0 & 0 & 0 & 1 & 1 & 0 & 1 & 0 & 0 & 1 & 0 & 0 & 1 \\ 0 & 0 & 0 & 0 & 1 & 0 & 0 & 0 & 0 & 1 & 0 & 1 & 0 & 0 & 0 & 1 & 1 & 0 & 1 & 0 & 0 & 1 & 1 \\ 0 & 0 & 0 & 0 & 1 & 0 & 0 & 0 & 1 & 0 & 1 & 0 & 0 & 1 & 1 & 1 & 0 & 0 & 1 & 0 & 0 & 0 & 1 \\ 0 & 0 & 0 & 0 & 1 & 0 & 0 & 1 & 0 & 0 & 0 & 1 & 1 & 0 & 0 & 0 & 0 & 1 & 0 & 1 & 0 & 1 & 1 \\ 0 & 0 & 0 & 0 & 1 & 0 & 0 & 1 & 0 & 1 & 0 & 0 & 1 & 0 & 1 & 0 & 0 & 0 & 1 & 0 & 1 & 0 & 1 \\ 0 & 0 & 0 & 0 & 1 & 1 & 0 & 0 & 1 & 1 & 0 & 0 & 1 & 0 & 0 & 1 & 0 & 0 & 0 & 1 & 0 & 0 & 1\end{matrix} ]$$

Where the bits in G⁸ can be packed into twenty-two 23-bit vectors to form g⁸.

$${ℊ}^{8} = [ \begin{matrix}{ℊ}_{0}^{8} \\ {ℊ}_{1}^{8} \\ {ℊ}_{2}^{8} \\ {ℊ}_{3}^{8} \\ {ℊ}_{4}^{8} \\ {ℊ}_{5}^{8} \\ {ℊ}_{6}^{8} \\ {ℊ}_{7}^{8} \\ {ℊ}_{8}^{8} \\ {ℊ}_{9}^{8} \\ {ℊ}_{10}^{8} \\ {ℊ}_{11}^{8} \\ {ℊ}_{12}^{8} \\ {ℊ}_{13}^{8} \\ {ℊ}_{14}^{8} \\ {ℊ}_{15}^{8} \\ {ℊ}_{16}^{8} \\ {ℊ}_{17}^{8} \\ {ℊ}_{18}^{8} \\ {ℊ}_{19}^{8} \\ {ℊ}_{20}^{8} \\ {ℊ}_{21}^{8}\end{matrix} ] = [ \begin{matrix}0 x0149f \\ 0 x03da1 \\ 0 x046e3 \\ 0 x09959 \\ 0 x0b067 \\ 0 x0cb25 \\ 0 x0e21b \\ 0 x10f13 \\ 0 x1262d \\ 0 x17451 \\ 0 x182d5 \\ 0 x1d0a9 \\ 0 x20ab9 \\ 0 x22387 \\ 0 x258c5 \\ 0 x31135 \\ 0 x34349 \\ 0 x428d3 \\ 0 x45391 \\ 0 x48c2b \\ 0 x4a515 \\ 0 x66489\end{matrix} ]$$

If the j^{th} 23-bit rotation of

$${ℊ}_{i}^{8}$$

is denoted as ror²³

$$( {ℊ}_{i}^{8} , j ) ,$$

then a set of 506, 23-bit masks,

$${M}_{k}^{8}$$

for 0≤k<506, can be computed according to Equation (3).

$${M}_{k}^{8} = {M}_{i , j}^{8} = r o {r}^{23} ( {g}_{i}^{8} , j )$$

for 0≤i<22, 0≤j<23 where k=23i+j Equation (3)

This set of masks is constant and can be tabularized, such that it can be indexed by both i and j, for computational efficiency. Every mask in

$${M}_{k}^{8}$$

for 0≤K<506 has a Hamming weight of 8. For any valid Golay codeword W, all the valid codewords that have a distance of 8 from W can be generated by applying each of the masks to the codeword W according to equation (4).

$$\begin{matrix}{C}_{k}^{8} ( W ) = W + {M}_{k}^{8} & for 0 \leq k < 506\end{matrix} \qquad Equation ( 4 )$$

Thus, for any valid Golay codeword, W, there are 506 other valid codewords that have a distance of 8 from W. The codewords can be computed by applying a set of masks to W.

$${C}_{k}^{7} ( W ) and {C}_{k}^{8} ( W )$$

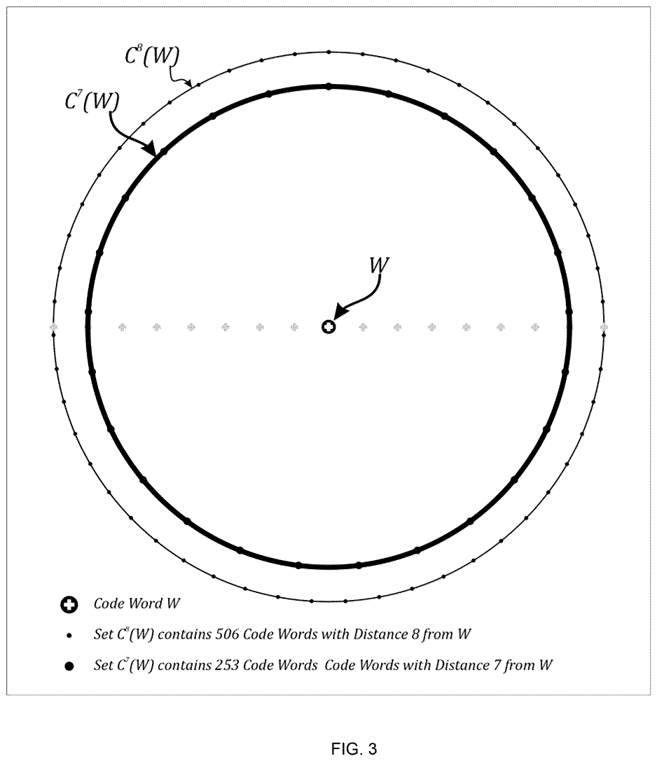

are combined to form a set including 759 codewords in total that have a distance of 8 or less from codeword W. FIG. 3 is a diagram illustrating a distance from codeword W to

$${C}_{k}^{7} ( W ) and {C}_{k}^{8} ( W ) .$$

The number of points indicating codewords shown is reduced to simplify FIG. 3. FIG. 3 illustrates the codeword W and the codewords that are closest to W. 253 codewords are on the inner circle, which has a distance of 7 from W, and 506 codewords are on the outer circle, which has a distance of 8 from W. As illustrated in FIG. 2, no codewords having a distance of 9 or 10 are available. FIG. 3 illustrates codeword W and its 759 closest neighbors.

A maximum likelihood (ML) soft-decision decoder can identify the valid codeword that is closest to a received codeword by evaluating the distance between the received codeword and every possible transmitted codeword. The ML decoder achieves the best theoretical decoder performance, but it comes at the cost of high computational complexity. The ML decoder can be modified such that a received codeword is first decoded using a conventional hard-decision Golay decoder to generate codeword W. The received codeword, R, is compared to W and each of its 759 closest neighbors, to generate a total of 760 distances. The performance of this modified ML decoder is very close to that of the ML decoder, while the number of codewords evaluated is reduced by more than 80 percent from 4096 down to 760. Additional techniques can further reduce the number of codeword distances evaluated from 760 down to 78 or fewer. This represents a complexity reduction of more than 98 percent relative to the ML decoder, with very little performance degradation. The modified ML decoder can choose a codeword that is within the smallest subset (e.g., 78 or fewer) of the codewords. Trading off a very slight bit of performance to significantly reduce complexity is beneficial in many circumstances.

The Golay (24,12) code is a similar derivative of the Golay (23,12) code, in which an additional parity bit is appended to each 23-bit codeword to generate a 24-bit codeword. The addition of a parity bit causes all the distance 7 codewords to become distance 8 codewords, such that there are 759 codewords in total that have a distance of 8 from a given codeword W.

Computing Subsets of the Golay Codeword Masks in M⁷ and M⁸

As described above, two sets of masks were defined, M⁷ and M⁸, which when applied to a codeword W, can generate all the valid Golay codewords that have a distance of 7 or 8 from the original codeword W. In some implementations, one or more subsets of M⁷ and M⁸ can be defined. M⁷ includes 253 masks that can be arranged into 11 rows, each row with 23 columns. M⁸ includes 506 masks that can be arranged into 22 rows, each row with 23 columns.

Set M⁷, including 253 masks, can be divided into 23 overlapping subsets, where each subset includes 77 (=11×7) masks. Each of the 23 subsets is referred to as M⁷[0] through M⁷[22]. Subset M⁷[0] is defined such that it includes every mask in M⁷ that has a one (the value of “1”) at bit position 0 (the LSB). Subset M⁷[1] is defined such that it includes every mask in M⁷ that has a one (the value of “1”) at bit position 1. This pattern continues for each bit position, until the final subset, M⁷[22], is defined such that it includes every mask in M⁷ that has a one (the value of “1”) at bit position 22 (the MSB). In a generalized form, the subset M⁷[a] (where 0≤a<23) is a subset of M⁷ that includes only the masks that have a one at bit position a (the value of bit a is 1). If M⁷[b] denotes a second subset of M⁷, where a≠b, then the intersection of the subset M⁷[a] with the subset M⁷[b] is denoted as M⁷[a, b].

$${M}^{7} [ a , b ] = {M}^{7} [ a ] ∩ {M}^{7} [ b ]$$

where a≠b

Similarly, the intersection of three different such subsets is denoted M⁷[a, b, c].

$${M}^{7} [ a , b , c ] = {M}^{7} [ a ] ⋂ {M}^{7} [ b ] ⋂ {M}^{7} [ c ]$$

where a≠b≠c

The number of masks in every possible M⁷[a, b] is 21, and the number of masks in every possible M⁷[a, b, c] is 5.

Similarly, set M⁸ can also be divided into 23 subsets denoted M⁸[0] through M⁸[22]. Each of the subsets includes 176 (=22×8) masks. The 23 subsets overlap each other since 23×176>506. In a generalized form, the subset M⁸[a] (where 0≤a<23) is a subset of M⁸ that includes only the masks that have a one at bit position a (the value of bit a is 1). If M⁸[b] denotes a second subset of M⁸, where a≠b, then the intersection of the subset M⁸[a] with the subset M⁸[b] is denoted as M⁸[a, b].

$${M}^{8} [ a , b ] = {M}^{8} [ a ] ⋂ {M}^{8} [ b ]$$

where a≠b

Similarly, the intersection of three different such subsets is denoted M⁸[a, b, c].

$${M}^{8} [ a , b , c ] = {M}^{8} [ a ] ⋂ {M}^{8} [ b ] ⋂ {M}^{8} [ c ]$$

where a≠b≠c

The number of masks in every possible M⁸[a, b] is 56, and the number of masks in every possible M⁸[a, b, c] is 16.

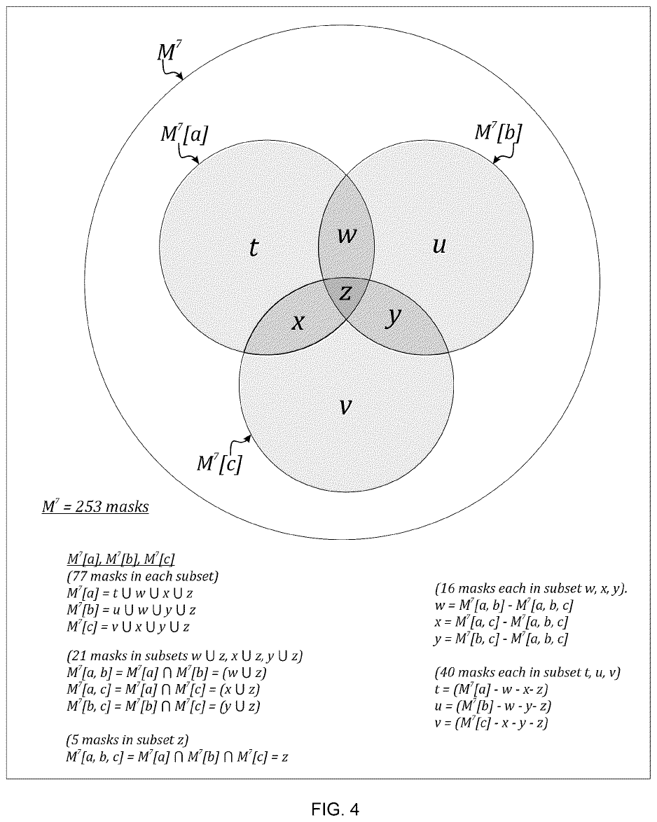

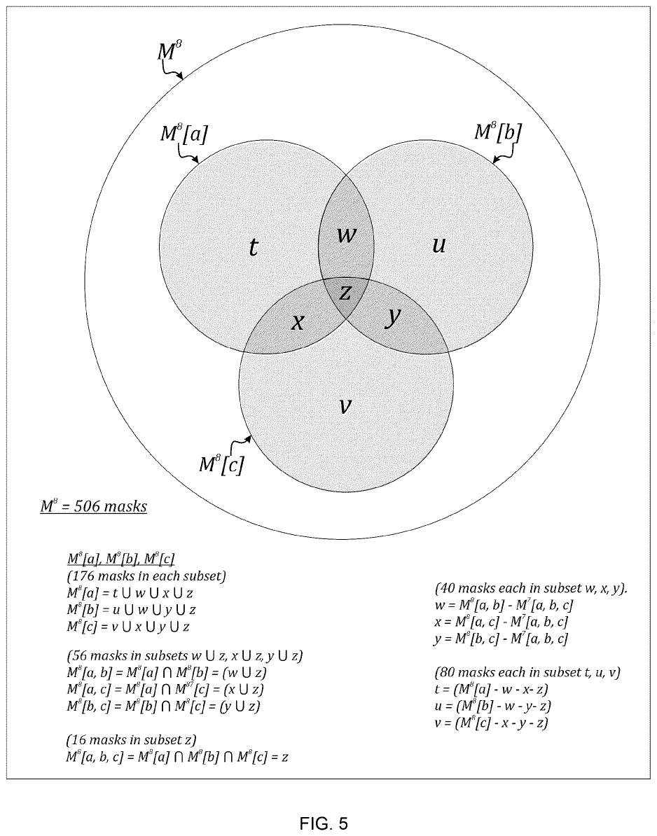

M⁷ and M⁸ are non-overlapping subsets from a set of 4096 masks needed to form a complete set of valid Golay (23,12) codes. Masks in M⁷ have a Hamming weight of 7 and masks in M⁸ have a Hamming weight of 8. The remaining masks have Hamming weights of 11 or greater. M⁷ and M⁸ can be used to generate a set of codewords that are closest to another codeword. FIG. 4 is a diagram illustrating M⁷, subsets M⁷[a], M⁷[b] and M⁷[c], and intersections among subsets M⁷[a], M⁷[b] and M⁷[c]. Similarly, FIG. 5 is a diagram illustrating M⁸, subsets M⁸[a], M⁸[b] and M⁸[c], and intersections among subsets M⁸[a], M⁸[b] and M⁸[c]. The subsets of M⁷ and M⁸ and their intersections are useful in the Golay decoder.

The subsets can be generated by scanning the entire set of masks and checking the required bits, which is computationally intensive. It is possible to derive the subsets in a simpler fashion. Consequently, methods for efficiently computing the subsets are described below.

To efficiently compute subsets M⁷[a] and M⁸[a], two additional matrices, S⁷ and S⁸, are defined as follows.

$${S}^{7} = [ \begin{matrix}0 & 2 & 4 & 5 & 6 & 10 & 11 \\ 0 & 1 & 3 & 6 & 8 & 10 & 13 \\ 0 & 3 & 9 & 10 & 11 & 12 & 14 \\ 0 & 1 & 4 & 5 & 7 & 8 & 15 \\ 0 & 2 & 3 & 7 & 11 & 13 & 15 \\ 0 & 2 & 7 & 8 & 10 & 14 & 16 \\ 0 & 1 & 6 & 11 & 14 & 15 & 16 \\ 0 & 1 & 4 & 6 & 9 & 12 & 17 \\ 0 & 4 & 8 & 11 & 13 & 14 & 17 \\ 0 & 5 & 6 & 7 & 13 & 16 & 17 \\ 0 & 2 & 6 & 9 & 13 & 14 & 18\end{matrix} ]$$

$${S}^{8} = [ \begin{matrix}0 & 1 & 2 & 3 & 4 & 7 & 10 & 12 \\ 0 & 5 & 7 & 8 & 10 & 11 & 12 & 13 \\ 0 & 1 & 5 & 6 & 7 & 9 & 10 & 14 \\ 0 & 3 & 4 & 6 & 8 & 11 & 12 & 15 \\ 0 & 1 & 2 & 5 & 6 & 12 & 13 & 15 \\ 0 & 2 & 5 & 8 & 9 & 11 & 14 & 15 \\ 0 & 1 & 3 & 4 & 9 & 13 & 14 & 15 \\ 0 & 1 & 4 & 8 & 9 & 10 & 11 & 16 \\ 0 & 2 & 3 & 5 & 9 & 10 & 13 & 16 \\ 0 & 4 & 6 & 10 & 12 & 13 & 14 & 16 \\ 0 & 2 & 4 & 6 & 7 & 9 & 15 & 16 \\ 0 & 3 & 5 & 7 & 12 & 14 & 15 & 16 \\ 0 & 3 & 4 & 5 & 7 & 9 & 11 & 17 \\ 0 & 1 & 2 & 7 & 8 & 9 & 13 & 17 \\ 0 & 2 & 6 & 7 & 11 & 12 & 14 & 17 \\ 0 & 2 & 4 & 5 & 8 & 12 & 16 & 17 \\ 0 & 3 & 6 & 8 & 9 & 14 & 16 & 17 \\ 0 & 1 & 4 & 6 & 7 & 11 & 13 & 18 \\ 0 & 4 & 7 & 8 & 9 & 12 & 14 & 18 \\ 0 & 1 & 3 & 5 & 10 & 11 & 15 & 18 \\ 0 & 2 & 4 & 8 & 10 & 13 & 15 & 18 \\ 0 & 3 & 7 & 10 & 13 & 14 & 17 & 18\end{matrix} ]$$

S⁷ includes 11 rows and 7 columns. The total number of values in S⁷ is 77. Notation of the form

$${S}_{i , j}^{7}$$

is used to denote the value in the ith row and jth column, where 0≤i<11 and 0≤j<7. The values in

$${S}_{i , j}^{7}$$

each denote a bit position such that

$$0 \leq {S}_{i , j}^{7} \leq 23.$$

The values in S⁷ can be derived from G⁷. For every value that is “1” in the matrix G⁷, the column index is stored in S⁷.

M⁷ is a set of masks which can be organized into 11 rows and 23 columns. The individual masks within M⁷ can be referenced by their row and columns using the notation

$${M}_{i , j}^{7}$$

where i specifies the row and j specifies the column. Equations (5) and (6) below are used to calculate the subset M⁷[a] including the masks from M⁷ that have a one at bit position a (the value of bit a is 1).

$$f ( i , j ) = ( {S}_{i , j}^{7} - a ) mod 23 \qquad Equation ( 5 )$$

$${{M}^{7} [ a ]}_{k} = {M}_{i , f ( i , j )}^{7} for 0 < k < 77 , 0 \leq i < 11 , 0 \leq j < 7 , where k + 7 i + j \qquad Equation ( 6 )$$

Accordingly, the subset can be obtained without scanning the entire set of masks in M⁷. Similarly, a subset M⁸[a] including the masks from M⁸ that have a one at bit position a (the value of bit a is 1), can be computed using the following Equations (7) and (8).

$$f ( i , j ) = ( {S}_{i , j}^{8} - a ) mod 23 \qquad Equation ( 7 )$$

$${{M}^{8} [ a ]}_{k} = {M}_{i , f ( i , j )}^{8} for 0 < k < 176 , 0 \leq i < 12 , 0 \leq j < 8 , where k = 8 i + j \qquad Equation ( 8 )$$

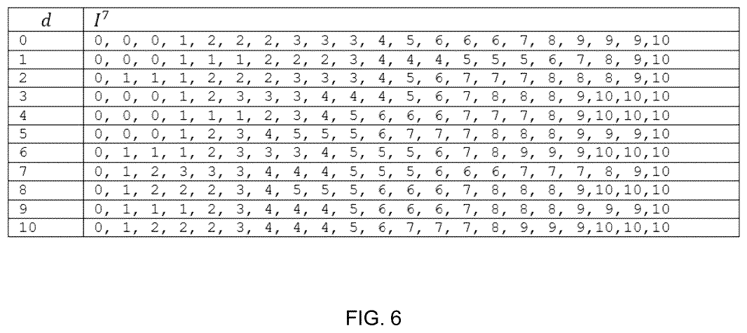

M⁷[a, b], which is the intersection of the subset M⁷[a] with subset M⁷[b], can be generated by first computing subset M⁷[a] and then checking each of the 77 masks in M⁷[a] for those that also have a one at bit position b (the value of bit b is 1), which is computationally intensive. Correspondingly, a less computationally complex method is described below. The methods for efficiently computing subsets M⁷[a, b] and M⁸[a, b] utilize tables as defined in FIGS. 6-9. FIG. 6 is a table illustrating I⁷ indices to

$${M}_{i , j}^{7}$$

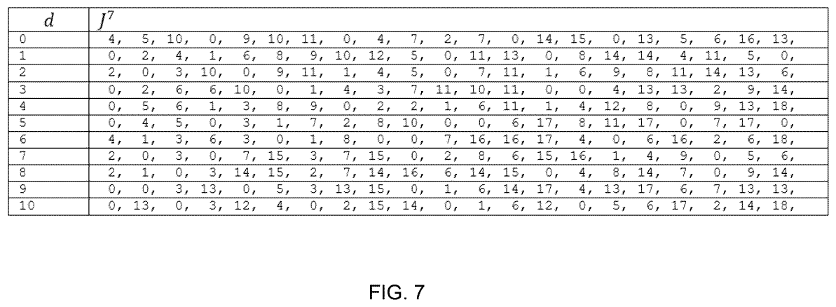

used to compute subsets M⁷[a, b]. FIG. 7 is a table illustrating J⁷ indices to

$${M}_{i , j}^{7}$$

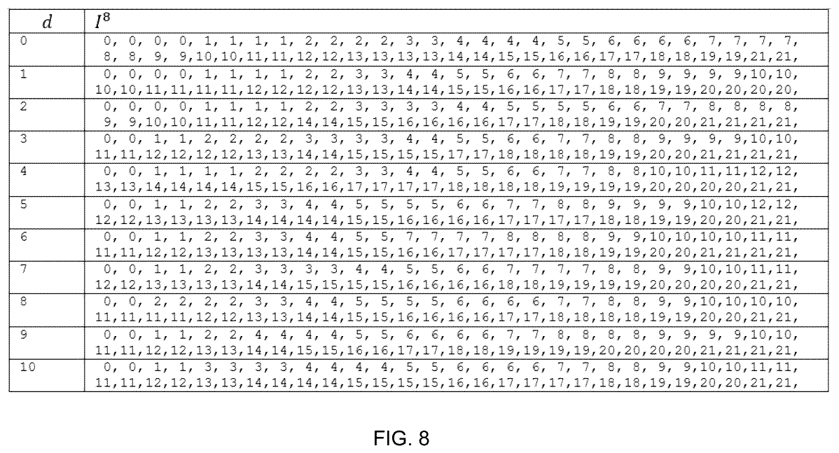

used to compute subsets M⁷[a, b]. FIG. 8 is a table illustrating I⁸ indices to

$${M}_{i , j}^{8}$$

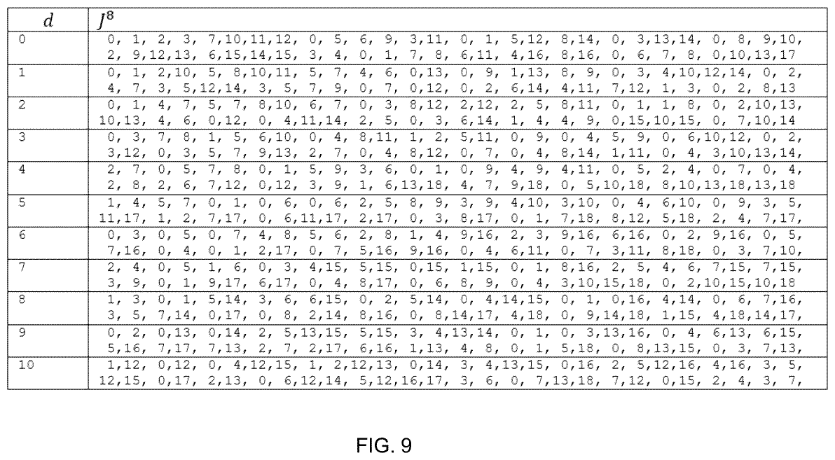

used to compute subsets M⁸[a, b]. FIG. 9 is a table illustrating J⁸ indices to

$${M}_{i , j}^{8}$$

used to compute subsets M⁸[a, b].

To compute subsets M⁷[a, b] or M⁸[a, b], a transformation on the pair (a, b) is performed to yield index pair (d, n) that are suitable for indexing the tables I⁷/J⁷ or I⁸/J⁸. Whereas, a and b are both bit positions within the masks in the set, d is a difference in the bit positions, and n is either bit position a or bit position b.

Prior to the transformation, b and a are ordered such that b>a, then the transformation is performed using the following sequence of equations (9)-(11).

$$δ = b - a \qquad Equation ( 9 )$$

$$where 0 < δ < 22$$

$$d = \{ \begin{matrix}δ - 1 & when δ < 12 \\ 22 - δ & otherwise\end{matrix} \qquad Equation ( 10 )$$

$$where 0 \leq d < 11$$

$$n = \{ \begin{matrix}a & when δ < 12 \\ b & otherwise\end{matrix} \qquad Equation ( 11 )$$

d is the difference in 23-bit rotation position between position a and b, where the difference between positions 22 and 0 is 1 (not 22). Then n is the number of 23-bit right rotations required to put the bit at position a or b into the LSB. If m=2^{a}+2^{b}, where b>a and b<23, then for any pair (a, b), there is a pair (d, n) such that if n is rotated (23-bit) right by n, the LSB will include a 1 and the remaining bit will be at position 11 or lower.

After the transformation, d is used as an index to the tables I^{7/8} and J^{7/8}. Index d selects an entire row from the appropriate tables. To select a subset of masks from M⁷, two vectors, Ī and J̅, each of length 21, are first formed by using the following two equations (12)-(13).

$${\overline{I}}_{k} = {I}_{d , k}^{7} for 0 \leq k \leq 20 \qquad Equation ( 12 )$$

$${\overline{J}}_{k} = ( {J}_{d , k}^{7} - n ) mod 23 for 0 \leq k \leq 20 \qquad Equation ( 13 )$$

Index d is used to select a row including 21 values from each of the tables, I⁷ and J⁷. The second coordinate from the transformation, n, is then used to apply an offset and modulo operation to achieve the required mask rotation. M⁷ includes 11 rows and 23 columns, and the values in each row are all related using a 23-bit rotation.

$${M}_{i , j}^{7}$$

is the mask in the ith row and the jth column of M⁷. Vectors Ī and J̅ represent 21 coordinate pairs for locating 21 masks within M⁷.

$${M}^{7} [ a , b ] = {M}_{{\overline{I}}_{k} , {\overline{J}}_{k}}^{7} for 0 \leq k \leq 20 \qquad Equation ( 14 )$$

Equation (14) is used to generate the subset M⁷[a, b]. Generating subset M⁸[a, b] from set M⁸ is very similar, except that the dimensions of the tables and vectors change. The length of the subset is 56, and the equations (15)-(17) are used to generate the subset M⁸[a, b].

$${\overline{I}}_{k} = {I}_{d , k}^{8} for 0 \leq k \leq 55 \qquad Equation ( 15 )$$

$${\overline{J}}_{k} = ( {J}_{d , k}^{8} - n ) mod 23 for 0 \leq k \leq 55 \qquad Equation ( 16 )$$

$${M}^{7} [ a , b ] = {M}_{{\overline{I}}_{k} , {\overline{J}}_{k}}^{7} for 0 \leq k \leq 55 \qquad Equation ( 17 )$$

Subset M⁷[a, b, c] can be generated by first generating the subset M⁷[a, b] having a length of 21, and then choosing the 5 masks within M⁷[a, b]. The chosen 5 masks have a one at bit position c (the value of bit c is 1). Thus, generating M⁷[a, b, c] is only slightly more complex than generating M⁷[a, b].

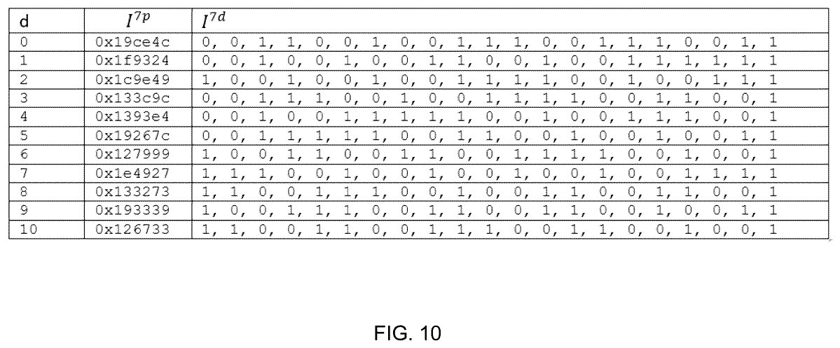

FIG. 10 is a table illustrating two alternate ways I^{7p} and I^{7d} to store I⁷. I⁷ can be stored differentially to form I^{7d} and then packed to form I^{7P}. The preferred way to store the I⁷ is specific to the implementation. I⁸ can be stored in a similar manner.

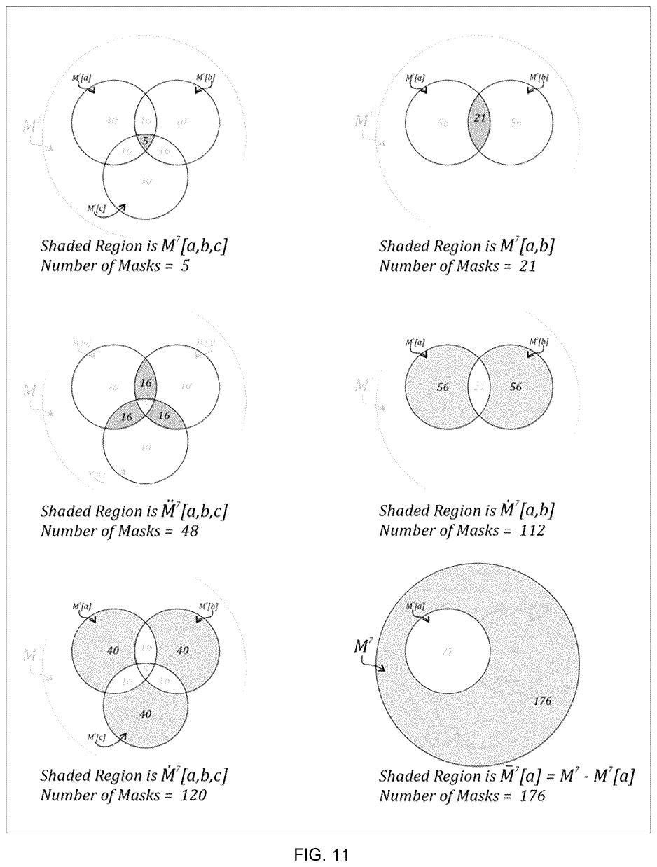

FIG. 11 is a diagram illustrating subsets that can be derived from intersections of M⁷[a], M⁷[b] and M⁷[c]. Each of the subsets shown is used for the soft-decision Golay decoder (an example of Soft-Decision Block Decoder 100 of FIG. 1). These subsets are beneficial, because the masks included in the subsets are used to create codewords, each codeword having the same distance. If R is a Golay codeword that includes 1, 2, or 3 errors and W is the corrected Golay decoder result, then R and W differ at 1~3 bit positions. For example, if the Golay decoder corrected a single bit at bit position 10. M⁷[10] includes 77 masks, each mask having a 1 at bit position 10. If 77 codewords are generated by applying each of the 77 masks to W, each of the codewords has a distance of 7 from W. However, the distance between R and each of the codewords is 6. Thus, each member of the subset is equidistant to R.

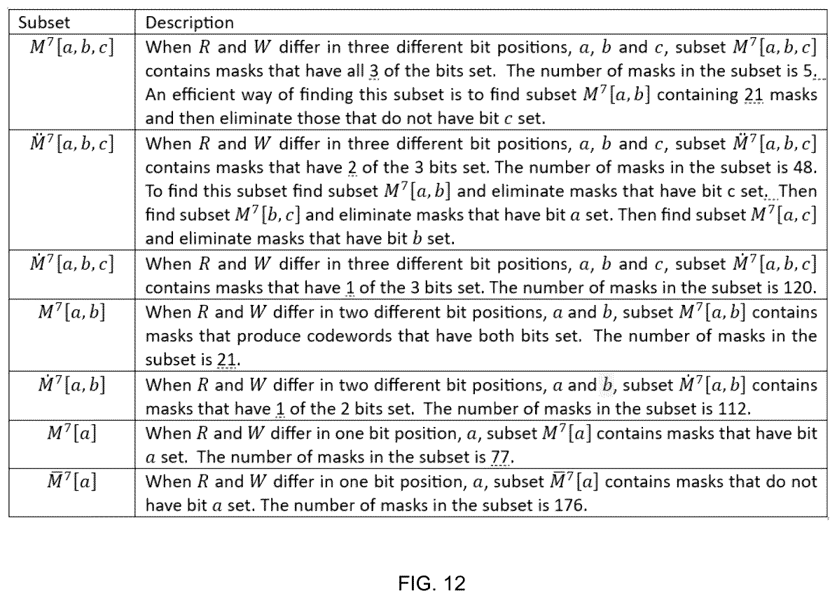

If the Golay decoder flipped two bits, at positions a and b, to obtain W from R, then the intersection of the subsets M⁷[a] and M⁷[b] generates codewords that are equidistant from R and have a distance of 5. Additionally, the masks that are in M⁷[a] but not M⁷[b] or in M⁷[b] but not M⁷[a] are equidistant from R and have a distance of 6. FIG. 12 is a table summarizing the subsets that are shown in FIG. 11. When applied to W, masks in each of the subsets generate codewords that are equidistant from R.

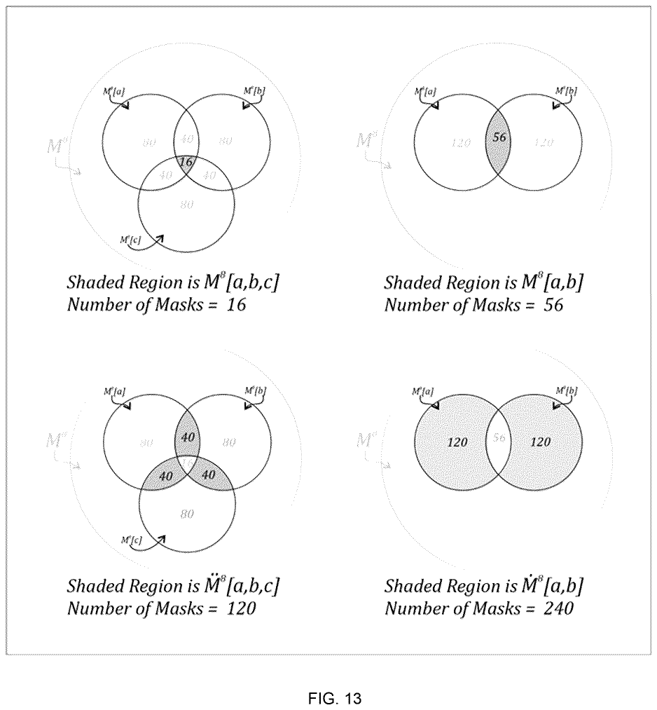

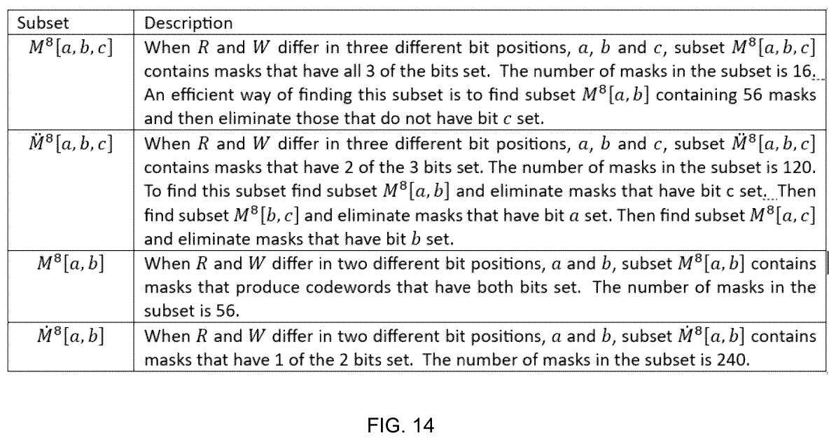

FIG. 13 illustrates subsets that can be derived from intersections of M⁸[a], M⁸[b] and M⁸[c]. Each of these subsets is also used for soft-decision Golay decoder. FIG. 14 is a table summarizing the subsets of M⁸.

### Properties of Hamming Codes

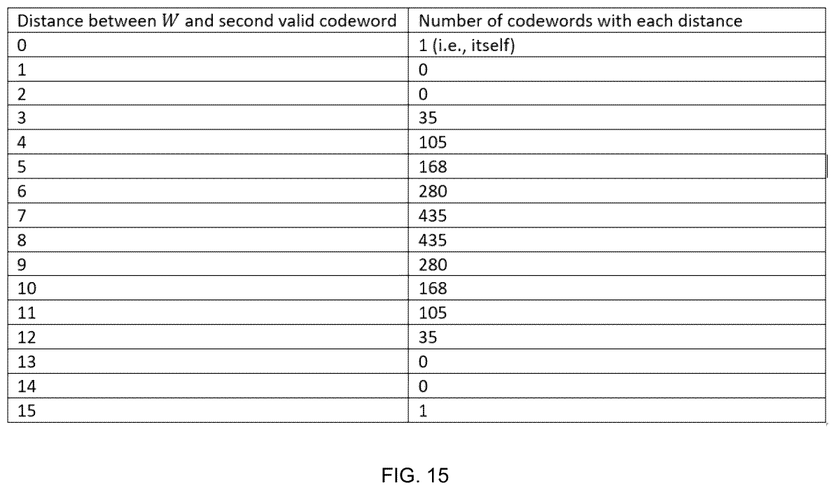

As to Hamming (15,11) codes, the number of unique codewords that may be transmitted is 2048. Like the Golay code, the codewords for a Hamming code can be generated in sets that are equidistant from another valid codeword, W. FIG. 15 is a table illustrating Hamming (15,11) code distance distribution properties.

To obtain a subset of all the Hamming codes that have a distance of 3 from another valid codeword W, each of the masks in the set H³ can be applied to codeword W. This can generate a set of 35 codewords having a distance of 3 from W. To obtain a subset of all the Hamming codes that have a distance of 4 from W, each of the masks in the set H⁴ can be applied to codeword W. This can generate a set of 105 codewords that have a distance of 4 from W.

The subsets of H³ and H⁴ are similar to the Golay masks in M⁷ and M⁸.

Subsets H³ [a] for 0≤a<15 can be precomputed and stored as 15 tables, each table having 7 codewords. This can be done by scanning H³ to obtain all the masks that have a one at each bit position (the value of each bit is 1). For instance, H³[0] includes all the masks from H³ that have a 1 in the LSB.

Subsets H⁴ [a] for 0≤a<15 can be precomputed and stored as 15 tables, each table having 28 codewords. This can be done by scanning H⁴ to obtain all the masks that have each bit set. For instance, H⁴[14] includes all the masks from H⁴ that have a 1 in the MSB.

$${H}^{3} = [ \begin{matrix}0 \times 0013 \\ 0 \times 0025 \\ 0 \times 0046 \\ 0 \times 0070 \\ 0 \times 0094 \\ 0 \times 00 a 2 \\ 0 \times 00 c 1 \\ 0 \times 0109 \\ 0 \times 0020 a \\ 0 \times 0310 \\ 0 \times 0418 \\ 0 \times 0502 \\ 0 \times 0601 \\ 0 \times 080 c \\ 0 \times 0920 \\ 0 \times 0 a 40 \\ 0 \times 0 c 80 \\ 0 \times 1028 \\ 0 \times 1104 \\ 0 \times 1280 \\ 0 \times 1440 \\ 0 \times 1801 \\ 0 \times 2048 \\ 0 \times 2180 \\ 0 \times 2204 \\ 0 \times 2420 \\ 0 \times 2802 \\ 0 \times 3010 \\ 0 \times 4088 \\ 0 \times 4140 \\ 0 \times 4220 \\ 0 \times 4404 \\ 0 \times 4810 \\ 0 \times 5002 \\ 0 \times 6001\end{matrix} ] {H}^{4} = [ \begin{matrix}0 \times 0036 & 0 \times 0055 & 0 \times 0063 \\ 0 \times 0087 & 0 \times 00 b 1 & 0 \times 00 d 2 \\ 0 \times 00 e 4 & 0 \times 011 a & 0 \times 012 c \\ 0 \times 01 c 8 & 0 \times 0219 & 0 \times 024 c \\ 0 \times 02 a 8 & 0 \times 0303 & 0 \times 0360 \\ 0 \times 0384 & 0 \times 040 b & 0 \times 0468 \\ 0 \times 048 c & 0 \times 0511 & 0 \times 0544 \\ 0 \times 05 a 0 & 0 \times 0612 & 0 \times 0624 \\ 0 \times 06 c 0 & 0 \times 0708 & 0 \times 0829 \\ 0 \times 084 a & 0 \times 0898 & 0 \times 0905 \\ 0 \times 0950 & 0 \times 0982 & 0 \times 0 a 06 \\ 0 \times 0 a 30 & 0 \times 0 a 81 & 0 \times 0 c 14 \\ 0 \times 0 c 22 & 0 \times 0 c 41 & 0 \times 100 d \\ 0 \times 1058 & 0 \times 108 a & 0 \times 1121 \\ 0 \times 1142 & 0 \times 1190 & 0 \times 1214 \\ 0 \times 1222 & 0 \times 1241 & 0 \times 1406 \\ 0 \times 1430 & 0 \times 1481 & 0 \times 1812 \\ 0 \times 1824 & 0 \times 18 c 0 & 0 \times 1908 \\ 0 \times 1 e 00 & 0 \times 200 e & 0 \times 2038 \\ 0 \times 2089 & 0 \times 2114 & 0 \times 2122 \\ 0 \times 2141 & 0 \times 2221 & 0 \times 2242 \\ 0 \times 2290 & 0 \times 2405 & 0 \times 2450 \\ 0 \times 2482 & 0 \times 2811 & 0 \times 2844 \\ 0 \times 28 a 0 & 0 \times 20 a 8 & 0 \times 2 d 00 \\ 0 \times 3003 & 0 \times 3060 & 0 \times 3084 \\ 0 \times 3300 & 0 \times 3408 & 0 \times 401 c \\ 0 \times 402 a & 0 \times 4049 & 0 \times 4106 \\ 0 \times 4130 & 0 \times 4181 & 0 \times 4205 \\ 0 \times 4250 & 0 \times 4282 & 0 \times 4421 \\ 0 \times 4442 & 0 \times 4490 & 0 \times 4803 \\ 0 \times 4860 & 0 \times 4884 & 0 \times 4 b 00 \\ 0 \times 4 c 08 & 0 \times 5011 & 0 \times 5044 \\ 0 \times 50 a 0 & 0 \times 5208 & 0 \times 5500 \\ 0 \times 6012 & 0 \times 6024 & 0 \times 60 c 0 \\ 0 \times 6108 & 0 \times 6600 & 0 \times 7800\end{matrix} ]$$

Computing Soft-Decision Distance with Weighted Sum of Hamming Distances

A received codeword, which may contain errors, is denoted by R. R includes L bits where L=23 for a Golay (23,12) code, L=24 for a Golay (24,12) code, and L=15 for a Hamming (15,11) code. The individual bits within R are denoted rᵢ for 0≤l<L. Each bit, rₗ, is an integer in the range 0 to 2^{B}-1, such that 0≤rₗ<2^{B}. rᵢ=0 is the most confident “0”, whereas rₗ=2^{B}-1 is the most confident “1”. Values for rₗ that fall between the two limits were received with less confidence. For example, when the number of bits in each soft-decision bit is 4 (B=4), rₗ=0 is the most confident “0”, rₗ=7 is the least confident “0”, rₗ=8 is the least confident “1”, and rₗ=15 is the most confident “1”. Each bit, rₗ, is a B-bit integer. Since R includes L soft-decision bits, and each soft-decision bit is a B-bit value, the total number of bits in R is B×L.

There are two different approaches to computing a distance between a received codeword, R, and another codeword, W. For example, if the number of bits per soft-decision bit, B, is 4, the received codeword length is 8 (L=8), and the codeword Wis 0x98; thus the bits in W are provided below.

$${w}_{7} = 1 , {w}_{6} = 0 , {w}_{5} = 0 , {w}_{4} = 1 , {w}_{3} = 1 , {w}_{2} = 0 , {w}_{1} = 0 , {w}_{0} = 0$$

In this example, assume that the received soft decision bits are as below.

$${r}_{7} = 15 , {r}_{6} = 1 , {r}_{5} = 4 , {r}_{4} = 11 , {r}_{3} = 13 , {r}_{2} = 2 , {r}_{1} = 0 , {r}_{0} = 8$$

There are two approaches to computing a soft-decision distance between W and R, leading to the same outcome. An approach to compute a soft-decision distance is based on the sum of absolute values,

$${\sum }_{i = 0}^{7} \vert 15 {w}_{i} - {r}_{i} \vert = 21 ,$$

which sums the distance between each bit of R and the corresponding bit in W. Thus, the distance between R and W is 21.

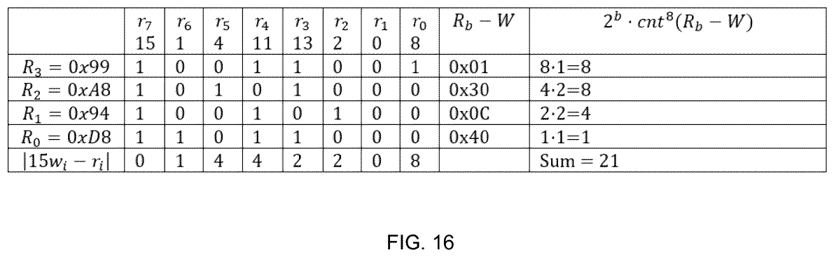

FIG. 16 is a table illustrating the computation of a soft-decision distance between R and W when B=4 and L=8. FIG. 16 illustrates the binary representations for r₀-r₇, with the MSB in the top row and the LSB in the bottom row. Also, the bits in each row are packed to create four codewords, R₀-R₃. Thus, the bits in R can be represented by either a series of codewords (R₀-R₃) or a series of soft-decision bits (r₀-r₇).

Representing a received soft-decision codeword as a series of codewords, rather than as a series of bits, allows the soft-decision distance to be computed in a different approach. The column in the FIG. 16 labeled “R_{b}−W” indicates the binary difference (same as exclusive-or) for each value of R_{b}. An alternative approach to computing the soft-decision distance is provided according to

$${\sum }_{b = 0}^{3} {2}^{b} \cdot {cnt}^{8} ( {R}_{b} - W ) = 21 ,$$

where the function cnt⁸(x) calculates an 8-bit Hamming weight on its argument. Thus, the distance computed using the alternative approach matches the distance computed using the above-mentioned original approach. The two approaches can produce the same result. A more generic form of computing the soft-decision distance using the alternative approach is provided according to Equation (18) below.

$$d = {\sum }_{b = 0}^{B - 1} {2}^{b} \cdot {cnt}^{L} ( {R}_{b} - W ) \qquad Equation ( 18 )$$

Where the function cnt^{L}(x) calculates an L-bit Hamming weight, which is the sum of L bits. The Hamming weight is implemented as a single-cycle instruction on many modern processors. It can be referred to as a population count or popent instruction, although other names may be used. The alternative approach of computing soft decision distances can provide benefits to reducing code complexity.

The two approaches can be compared. A generic form of the original approach for calculating the soft-decision distance can be provided according to Equation (19).

$$\dot{d} = {\sum }_{l = 0}^{L - 1} \vert {r}_{l} - K \cdot {w}_{l} \vert , where K = ( {2}^{B} - 1 ) \qquad Equation ( 19 )$$

If the multiply (K·wₗ) in the Equation (19) that computes \dot{d} is ignored (since there may be ways to avoid it), then Equation (19) requires L differences, L absolute values, and L−1 sums. If each operation requires a single cycle, then the number of cycles is 3L−1. The Equation (18) that computes d requires B differences, B Hamming weights, B−1 shifts, and B−1 adds. If each operation requires a single cycle, then the number of cycles is 4^{B}−2. Thus, if B<(3L+1)/4, the approach that uses the Hamming weight (Equation (18)) to compute soft-decision distance can use fewer cycles. The value of B is approximate and may vary when implemented on different processors. As to a Golay (23,12) code, L=23, computing the distances with a Hamming weight would use fewer cycles if B<17.5. As to a Hamming (15,11) code, L=15, computing distance with a Hamming weight would use fewer cycles if B<11.5. In practice, soft-decision decoding performance improves as B increases, while the rate of improvement drops off rapidly as B increases, such that there is not much benefit to using B>7. Thus, it can be expected that the approach of computing soft-decision distances using the Hamming weight requires fewer cycles for Golay codes and Hamming codes. Either approach for computing soft-decision distance may be used since they produce the same result.

Representing a soft-decision codeword, R, as a series of codewords, R_{b} for 0≤b<B, rather than as a series of soft-decision bits, rₗ for 0≤l<L, has an additional advantage. R_{B-1} is the hard-decision representation for codeword R, since it includes the MSB of each soft-decision bit, packed into a codeword. R_{B-1} is the most significant codeword. One additional advantage is that the number of load instructions required to access the codeword is B, rather than L. Usually storing the soft-decision codeword as a series of codewords is more compact and uses less memory.

### Soft-Decision Golay (23,12) Decoder

As discussed earlier, Golay (23,12) code has 4096 valid Golay codes. Further, as to a given valid codeword, W, within the set of valid Golay codewords, there are 253 valid codewords that have a distance of 7 from W. In addition, there are 506 valid codewords that have a distance of 8 from W. Moreover, a set of masks is applied to the original codeword, W, to obtain all the nearest codewords. An ML-decoder evaluates the distance between a received codeword, R, and each of the 4096 valid Golay codewords. Simulations have shown that there is a negligible decoder performance decrease if the codeword search is reduced to include only those codewords that have a distance less than or equal to 8 from the hard-decision decoder result.

However, it is possible to further reduce the size of the codeword search to obtain an even greater complexity reduction. As to Golay (23,12), the number of codewords searched can be reduced to 78 or less, while still having very little impact on decoding performance. A method to reduce the search down to 78 or fewer codewords will be described below.

As to the Golay (23,12) code, the received B-bit soft-decision codeword is denoted R and is represented by a series of B 23-bit codewords. The hard-decision information from R is included in the most significant codeword and is denoted R_{B-1}. The Golay decoded R_{B-1} is denoted W. The Hamming distance between R_{B-1} and W is denoted f. The set of 253 codewords that each have a distance of 7 from W is denoted C⁷(W) and the set of 506 codewords that each have a distance of 8 from W is denoted C⁸(W). The entire set of candidate codewords, C^{T}={W, C⁷(W), C⁸(W)}, includes a total of 760 codewords. An ML decoder computes the distance between a received codeword, R, and each of the 4096 possible transmitted codewords. Reducing the number of candidates from 4096 to 760 results in a reduced complexity ML decoder. The distances between the codewords of the set C^{T} and R are computed as soft-decision distances. The hard-decision distances between the codewords of set C^{T} and R_{B-1} are also considered, because the hard-decision distances can be used to further reduce the number of codewords that need to be evaluated. R_{B-1} holds over half the total weight of R and is more important than the remaining soft-decision bits combined. This is because the weight of R_{B-1} is 2^{B-1} whereas the total weight of the remaining soft-decision bits is

$${\sum }_{b = B - 2}^{0} {2}^{b}$$

which is less than 2^{B}-1. If each of the 760 codewords in C^{T} is denoted

$${C}_{i}^{T}$$

for 0≤i<760, the Hamming distance between R_{B-1} and each codeword candidate in

$${C}_{i}^{T}$$

can be computed according to Equation (20).

$${d}_{i} = {cnt}^{23} ( {C}_{i}^{T} - {R}^{H} ) for 0 \leq i < 760 \qquad Equation ( 20 )$$

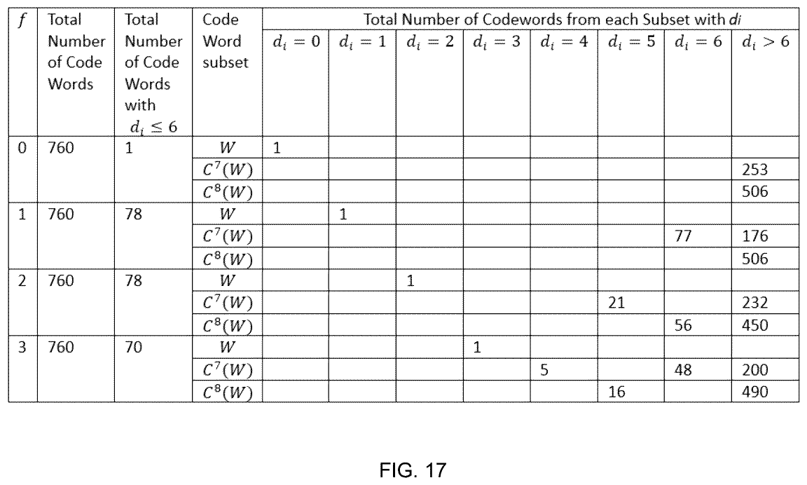

If the hard-decision distance is calculated for all 760 codewords, a pattern can be observed, as shown in FIG. 17, which is a table illustrating the number of codewords that have various distances for each value of f.

As shown in FIG. 17, the data in each row is gathered when f is 0, 1, 2, or 3, where f is the number of bits that were flipped by the hard-decision Golay Decoder, i.e., f=cnt²³(R_{B-1}−W). For any R_{B-1} and W such that W=gd^{23,12}(R_{B-1}) and f=cnt²³(R_{B-1}−W), the distances between R_{B-1} and every codeword in the set C^{T} can take on one of four possible distributions, and the distribution is determined by the value of f. For example, if f is 2, there are 21 codewords from C⁷(W) that have a distance of 5, and the remaining codewords in C⁷(W) have a distance greater than 6. Additionally, when f is 2, there are 56 codewords in C⁸(W) that have a distance of 6, and the remaining code words in C⁸(W) have a distance greater than 6. When f is 2, the codeword W has a distance of 2.

When f=0 (the Golay decoder did not flip any bits to obtain W from R_{B-1}, and R_{B-1} is a valid Golay codeword), there is only one candidate that has dᵢ=0, and all remaining candidates have dᵢ>6. A single candidate,

$${C}_{0}^{T} = W ,$$

is obtained, and it is the hard-decision decoder result.

When f=1 (the Golay decoder flipped one bit to obtain W from R_{B-1}), the hard-decision decoder result,

$${C}_{0}^{T} = W ,$$

has d₀=1, and there are 77 candidates from C⁷(W) that have dᵢ=6. The remaining candidates in

$${C}_{i}^{T}$$

all nave dᵢ>6.

When f=2 (the Golay decoder flipped two bits to obtain W from R_{B-1}): (1) the hard-decision decoder result,

$${C}_{0}^{T} = W ,$$

has d₀=2, (2) there are 21 codewords from C⁷(W) that have d=5, (3) there are 56 codewords from C⁸(W) that have d=6, and (4) All remaining codewords in C^{T} have a distance greater than 6.

When f=3 (the Golay decoder flipped three bits to obtain W from R_{B-1}): (1) the hard-decision decoder result,

$${C}_{0}^{T} = W ,$$

had d₀=3, (2) there are 5 codewords from C⁷(W) that have d=4, (3) there are 48 codewords from C⁷(W) that have d=6, (4) there are 16 codewords from C⁸(W) that have d=5, and (5) All remaining codewords in C^{T} have a distance greater than 6.

For example, when f=2, the hard-decision Golay decoder flipped 2 bits at positions a and b to obtain W from R_{B-1}. FIG. 17 indicates that there is a single codeword with dᵢ=2, 21 codewords with dᵢ=5, and 56 codewords with dᵢ=6. The remaining codewords have a distance greater than 6. Moreover, the 21 codeword candidates that have dᵢ=5 can be formed by applying a set of 21 masks to W, where the set of masks is M⁷[a, b]. The 56 codeword candidates that have dᵢ=6 can be generated by applying a set of 56 masks to W, where the set of masks is M⁸[a, b]. M⁷[a, b] is the subset of masks in M⁷ that have both bits a and b set and M⁸[a, b] is the subset of masks in M⁸ that have both bits a and b set. An efficient method for computing subsets M⁷[a, b] and M⁸[a, b] was described previously.

Similarly for other values of f, the candidates that have a distance less than 7 can be generated using other subsets of M⁷ and/or M⁸. For a given value of f, there is a pattern of codewords distances, and the codewords that have each distance can be generated from subsets of M⁷ and/or M⁸.

If the set of candidates is further reduced to include only codewords that have a distance less than or equal to 6 from R_{B-1}, the total number of codewords to be searched is reduced to 78 or fewer. Simulation confirms that eliminating codeword candidates with d>6 reduces decoder performance by a negligible amount in comparison to the complexity reduction achieved. Just as reducing the number of Golay candidates from 4096 down to 760 yields significant complexity reduction with little negative impact on decoder performance, further reducing the set of codeword candidates down to only those with dᵢ≤6 also results in a significant complexity reduction with negligible impact on decoder performance. Reducing the number of codeword candidates from 4096, as the ML decoder needs, down to 78 or fewer represents a complexity reduction for the codeword search of over 98%.

### Process of Soft-Decision Golay (23,12) Decoder

Soft-Decision Golay (23,12) decoder is an example of Soft-Decision block decoder 100 of FIG. 1. Thus, the process of Soft-Decision Golay (23,12) decoder is described in reference to FIG. 1. The input to the soft-decision Golay (23,12) decoder is a soft-decision codeword, R, which contains B separate 23-bit codewords, denoted R_{B-1} through R₀, where B is the number of bits per soft-decision bit. R_{B-1} is the most significant codeword and is the best hard-decision representation for R.

The first step in the process of soft-decision Golay (23,12) decoder is to Golay decode the hard-decision codeword contained in R_{B-1} to generate a corrected codeword W according to Equation (21). Additional codeword candidates that are “near” W will be evaluated by the soft-decision algorithm.

$$W = g {d}^{23 , 12} ( {R}_{B - 1} ) \qquad Equation ( 21 )$$

Next, δ, the binary difference between R_{B-1} and W is computed according to Equation (22).

$$δ = W - {R}_{B - 1} \qquad Equation ( 22 )$$

δ is a 23-bit value, which has a 1 in any bit position that was flipped by the Golay decoder to obtain W from (R_{B-1}). Between 0 and 3 bits (inclusive) may be flipped by the Golay decoder. Next, f, the number of bits that were flipped by the Golay decoder to obtain W from (R_{B-1}) is calculated via the following Equation (23).

$$f = c n {t}^{23} ( δ ) \qquad Equation ( 23 )$$

cnt²³(x) function computes a sum of 23 bits to produce a Hamming weight. The Golay (23,12) decoder can flip between 0 and 3 bits of the input to obtain the valid codeword nearest to the input. Thus, 0≤f≤3. When f is 1, the Golay decoder flipped a single bit to obtain W from R_{B-1}, and the position of the bit flipped is an integer in the range of 0 to 22. This position is denoted n₀. When f is 2, the Golay decoder flipped two different bits to obtain W from R_{B-1}, and the positions of the bits flipped are both integers in the range of 0 to 22. The positions are denoted n₀ and n₁, where n₀<n₁. When f is 3, the Golay decoder flipped three different bits to obtain W from R_{B-1}, and the positions of the bits flipped are all integers in the range of 0 to 22. The positions are denoted n₀, n₁ and n₂, where n₀<n₁<n₂.

After computing f, a set of masks is computed by the following Equation (24).

$$m = \{ \begin{matrix}\{ 0 \} & when f = 0 \\ \{ {M}^{7} [ {n}_{0} ] , 0 \} & when f = 1 \\ \{ {M}^{8} [ {n}_{0} , {n}_{1} ] , {M}^{7} [ {n}_{0} , {n}_{1} ] , 0 \} & when f = 2 \\ \begin{matrix}\{ {\ddot{M}}^{7} [ {n}_{0} , {n}_{1} , {n}_{2} ] , \\ {M}^{8} [ {n}_{0} , {n}_{1} , {n}_{2} ] , {M}^{7} [ {n}_{0} , {n}_{1} , {n}_{2} ] , 0 \}\end{matrix} & when f = 3\end{matrix} \qquad Equation ( 24 )$$

Different subsets of M⁷ and M⁸ are used depending on the value of f. These subsets are selected because they include the masks within M⁷ and M⁸ that can produce a hard-decision distance of 6 or less. The definitions of these subsets and approaches for computing them are described earlier. The length of the set of masks, m, is denoted by K, and is computed according to Equation (25).

$$K = \{ \begin{matrix}1 & when f = 0 \\ 78 ( 77 + 1 ) & when f = 1 \\ 78 ( 56 + 21 + 1 ) & when f = 2 \\ 70 ( 48 + 16 + 5 + 1 ) & when f = 3\end{matrix} \qquad Equation ( 25 )$$

Next, each mask in set m is applied to codeword W to obtain c according to equation (26), which includes a set of K codeword candidates.

$${c}_{k} = W + {m}_{k} 0 \leq k < K \qquad Equation ( 26 )$$

The hard-decision distance, between R_{B-1} and each codeword candidate, cₖ, is computed according to Equation (27).

$$d = \{ \begin{matrix}\{ {\{ 0 \}}_{1} \} & when f = 0 \\ \{ {\{ 6 \}}_{77} , {\{ 1 \}}_{1} \} \} & when f = 1 \\ \{ {\{ 6 \}}_{56} , {\{ 5 \}}_{21} , {\{ 2 \}}_{1} \} & when f = 2 \\ \{ {\{ 6 \}}_{48} , {\{ 5 \}}_{16} , {\{ 4 \}}_{5} , {\{ 3 \}}_{1} \} & when f = 3\end{matrix} \qquad Equation ( 27 )$$

Where the notation {a}_{b} is a vector including b repetitions of member a. Note that these distances d are generated without the use of a Hamming weight function. A vector of soft-decision distances \dot{d}ₖ is then computed for every codeword candidate in set c according to Equation (28).

$${\dot{d}}_{k} = {2}^{B - 1} \cdot {d}_{k} + {\sum }_{b = B - 2}^{0} {2}^{b} \cdot {cnt}^{23} ( {c}_{k} - {R}_{b} ) for 0 \leq k < K \qquad Equation ( 28 )$$

Equation (28) generates a soft-decision distance vector that compensates for the soft-decision confidence of every bit in the received codeword, R.

The codeword from set c that generates the lowest soft-decision distance, \dot{d}ₖ, is chosen as the output from the soft-decision Golay (23,12) decoder. In some implementations, N best outputs, rather than a single output codeword, may be generated.

A confidence metric can be calculated when N>1. The confidence metric is the difference between the best distance and the second-best distance. As to hard-decision and no bit errors, two different Golay codes differ in at least 7-bit positions. When there are no bit errors, the best distance is 0 and the second-best distance is 7.

### Process of Soft-Decision Golay (24,12) Decoder

The process of the soft-decision Golay (24,12) decoder is quite similar to the process of the Golay (23,12) decoder. The Golay (24,12) code is a Golay (23,12) code with a parity bit added. For each 24-bit codeword, the upper 23-bits are a Golay (23, 12) codeword, and the LSB is a parity bit chosen to make the parity of the 24-bit codeword even.

The input to the soft-decision Golay (24,12) decoder is R, which includes B separate 24-bit codewords, denoted R_{B-1} through R₀, where B is the number of bits per soft-decision bit. R_{B-1} is the most significant codeword.

The first step in the process of soft-decision Golay (24,12) decoder is to Golay decode the hard-decision codeword included in R_{B-1} to generate a corrected codeword W. Additional codeword candidates that are “near” W will be evaluated by the soft-decision algorithm.

The Golay (24,12) decoder uses a hard-decision Golay (23,12) decoder to decode the most significant 23 bits of R_{B-1}. The parity bit in the LSB of R_{B-1} is analyzed separately. The following Equation (29) computes R which is the most significant 23 bits from R_{B-1}.

$$\dot{R} = \frac{{R}_{B - 1}}{2} \qquad Equation ( 29 )$$

Then following Equation (30) computes Ry that is the MSB of the received soft-decision parity bit.

$${R}_{p} = {R}_{B - 1} mod 2 \qquad Equation ( 30 )$$

A hard-decision Golay (23,12) decoder is used to decode \dot{R}, generating the corrected 23-bit codeword \dot{W} according to Equation (31).

$$\dot{W} = g {d}^{23 , 12} ( \dot{R} ) \qquad Equation ( 31 )$$

Wₚ is computed according to Equation (32).

$${W}_{p} = c n {t}^{23} ( \dot{W} ) mod 2 \qquad Equation ( 32 )$$

If \dot{W} has odd parity then Wₚ=1, otherwise Wₚ=0. This computes the appropriate parity bit similarly to what the Golay (24,12) encoder does. The binary difference between \dot{W} and \dot{R} is computed according to Equation (33), and the binary difference between Wₚ and Rₚ is computed according to Equation (34).

$$δ = \dot{W} - \dot{R} \qquad Equation ( 33 )$$

$$p = {W}_{p} - {R}_{p} \qquad Equation ( 34 )$$

The differences are binary differences. δ is a 23-bit value, which has a 1 in any bit position that was flipped by the Golay decoder to obtain \dot{W} from \dot{R}. The parity bit difference, p, is a single bit that is 1 if Wₚ and Rₚ are the same and 0 if they are different. f, the number of bits that were flipped by the Golay decoder (excluding the parity bit) to obtain \dot{W} from \dot{R} is calculated via the following Equation (35).

$$f = c n {t}^{23} ( δ ) \qquad Equation ( 35 )$$

cnt²³(x) function computes a sum of 23 bits to generate a Hamming weight. The Golay (24,12) decoder can flip between 0 and 3 bits of the upper 23 bits of the input to obtain the valid codeword nearest to the input, and the parity bit may be flipped as well. Thus, 0≤f≤3 and 0≤p≤1.

When f is 1, the Golay decoder flipped a single bit to obtain \dot{W} from \dot{R}, and the position of the bit flipped is an integer in the range of 0 to 23. This position is denoted n₀. When f is 2, the Golay decoder flipped two different bits to obtain \dot{W} from \dot{R}, and the positions of the bits flipped are both integers in the range of 0 to 23. The positions are denoted n₀ and n₁. When f is 3, the Golay decoder flipped three different bits to obtain \dot{W} from \dot{R}, and the positions of the bits flipped are all integers in the range of 0 to 23. The positions are denoted n₀, n₁ and n₂.

When p=1, a set of masks, m, is computed according to Equation (36).

$$m = \{ \begin{matrix}\{ {M}^{7} , 0 \} & if f = 0 \\ \{ {M}^{8} [ {n}_{0} ] , {\overline{M}}^{7} [ {n}_{0} ] , {M}^{7} [ {n}_{0} ] , 0 \} & if f = 1 \\ [ {M}^{8} [ {n}_{0} , {n}_{1} ] , {\dot{M}}^{7} [ {n}_{0} , {n}_{1} ] , {M}^{7} [ {n}_{0} , {n}_{1} ] , 0 \} & if f = 2 \\ \begin{matrix}{\ddot{M}}^{8} [ {n}_{0} , {n}_{1} , {n}_{2} ] , {\dot{M}}^{7} [ {n}_{0} , {n}_{1} , {n}_{2} ] , {M}^{8} [ {n}_{0} , {n}_{1} , {n}_{2} ] , \\ {\ddot{M}}^{7} [ {n}_{0} , {n}_{1} , {n}_{2} ] , {M}^{7} [ {n}_{0} , {n}_{1} , {n}_{2} ] , 0 \}\end{matrix} & if f = 3\end{matrix} \qquad Equation ( 36 )$$

Alternatively, when p=0, a set of masks, m, is computed according to Equation (37).

$$m = \{ \begin{matrix}\{ 0 \} & if f = 0 \\ \{ {M}^{8} [ {n}_{0} ] , {M}^{7} [ {n}_{0} ] , 0 \} & if f = 1 \\ [ {\dot{M}}^{8} [ {n}_{0} , {n}_{1} ] , {\dot{M}}^{7} [ {n}_{0} , {n}_{1} ] , {M}^{8} [ {n}_{0} , {n}_{1} ] , {M}^{7} [ {n}_{0} , {n}_{1} ] , 0 \} & if f = 2 \\ \{ {\ddot{M}}^{8} [ {n}_{0} , {n}_{1} , {n}_{2} ] , {\ddot{M}}^{7} [ {n}_{0} , {n}_{1} , {n}_{2} ] , {M}^{8} [ {n}_{0} , {n}_{1} , {n}_{2} ] , {M}^{7} [ {n}_{0} , {n}_{1} , {n}_{2} ] , 0 \} & if f = 3\end{matrix} \qquad Equation ( 37 )$$

Equation (36) or (37) is considerably more complex than the corresponding equation (24) for the Golay (23,12) decoder. The subsets of masks selected are dependent upon both f and p. These subsets are selected because they include the masks within M⁷ and M⁸ that can generate a hard-decision distance of 8 or less. The definitions of these subsets and approaches for computing them are described earlier. The length of the set of masks, m, is denoted by K, and is computed according to Equation (38).

$$K = \{ \begin{matrix}1 & when f + p = 0 \\ 254 & when f + p = 1 \\ 430 & when f + p = 2 \\ 190 & when f + p = 3 \\ 310 & when f + p = 4\end{matrix} \qquad Equation ( 38 )$$

The set m is a set of 23-bit masks that do not include a parity bit. Set m is converted to a new set of 24-bit masks in \dot{m}, by shifting each mask in set m left by one and inserting a parity bit into the LSB to make all the masks have even parity (with eight ones) according to Equation (39). All the masks from m that are subsets of M⁷ have a parity bit of 1, and the remaining masks have a parity bit of 0.

$${\dot{m}}_{k} = \{ \begin{matrix}2 \cdot {m}_{k} + 1 & when {m}_{k} ∈ {M}^{7} \\ 2 \cdot {m}_{k} + 0 & otherwise\end{matrix} \qquad Equation ( 39 )$$

Next, each mask in the set m is applied to codeword W to obtain c, which includes a set of K codeword candidates, according to Equation (40).

$${c}_{k} = W + {\dot{m}}_{k} for 0 \leq k < K \qquad Equation ( 40 )$$

The hard-decision distance, between R_{B-1} and each codeword candidate, cₖ, is computed as follows.

$$d = \{ \begin{matrix}\{ {\{ 0 \}}_{1} \} & when f + p = 0 \\ \{ {\{ 7 \}}_{253} , {\{ 1 \}}_{1} \} \} & when f + p = 1 \\ \{ {\{ 8 \}}_{352} , {\{ 6 \}}_{77} , {\{ 2 \}}_{1} \} & when f + p = 2 \\ \{ {\{ 7 \}}_{168} , {\{ 5 \}}_{21} , {\{ 3 \}}_{1} \} & when f + p = 3 \\ \{ \{ {8}_{240} , \{ {\{ 6 \}}_{64} , {\{ 4 \}}_{6} \} & when f + p = 4\end{matrix} \qquad Equation ( 41 )$$

Where the notation {a}_{b} is a vector including b repetitions of member a. These distances are generated without the use of a Hamming weight function. A soft-decision distance vector, d, is computed for every codeword candidate in set c.

$${\dot{d}}_{k} = {2}^{B - 1} \cdot {d}_{k} + {\sum }_{b = B - 2}^{0} {2}^{b} \cdot {cnt}^{24} ( {c}_{k} - {R}_{b} ) for 0 \leq k < K \qquad Equation ( 42 )$$

Equation (42) generates a set of distances that compensate for the soft-decision confidence of every bit in the received codeword, R.

The codeword from set c that generates the lowest soft-decision distance, \dot{d}ₖ, is chosen as the output from the soft-decision Golay (24,12) decoder. In some implementations, the N best outputs, rather than a single output codeword, are generated.

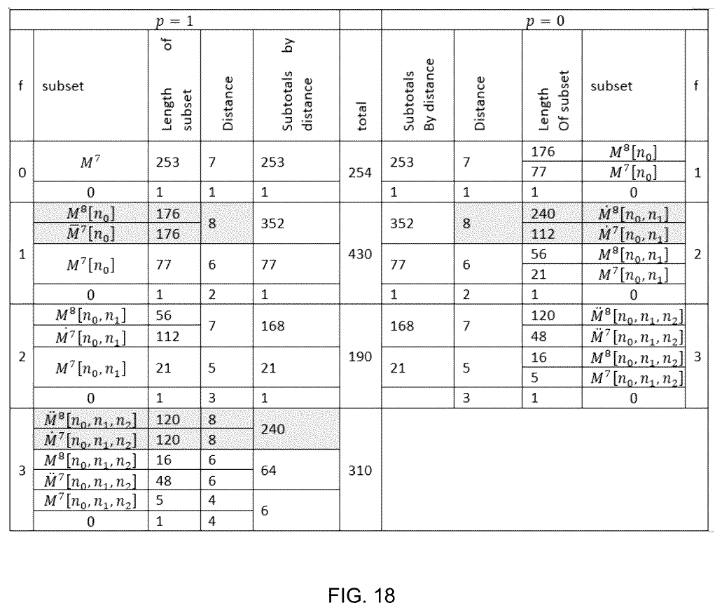

FIG. 18 is a table illustrating a summary of the subsets of masks used to compute set m, the length of each subset, and the distances corresponding to each subset.

### Alternative Process of Soft-Decision Golay (24,12) Decoder

An alternative process of Golay (24,12) decoder is very similar to the process of the Golay (24,12) decoder described above. The alternative process can reduce the decoding complexity with a slight decoding performance tradeoff. The sets of masks in m and m are reduced to exclude the subsets of masks (M⁸[n₀], M̅⁷[n₀], \dot{M}⁸[n₀, n₁], \dot{M}⁷[n₀, n₁]) in FIG. 18. The shaded regions (M⁸[n₀], M̅⁷[n₀], \dot{M}⁸[n₀, n₁], \dot{M}⁷[n₀, n₁]) include masks that result in a codeword distance of 8. This optimization reduces the mask set down to those that generate codewords with a distance of 7 or less from R_{B-1}.

The Equation (43) for m when p=1 is provided below, in contrast to Equation (36).

$$m = \{ \begin{matrix}\{ {M}^{7} , 0 \} & if f = 0 \\ \{ {M}^{7} [ {n}_{0} ] , 0 \} & if f = 1 \\ [ {M}^{8} [ {n}_{0} , {n}_{1} ] , {\dot{M}}^{7} [ {n}_{0} , {n}_{1} ] , {M}^{7} [ {n}_{0} , {n}_{1} ] , 0 \} & if f = 2 \\ \begin{matrix}\{ {M}^{8} [ {n}_{0} , {n}_{1} , {n}_{2} ] , {\ddot{M}}^{7} [ {n}_{0} , {n}_{1} , {n}_{2} ] , \\ {M}^{7} [ {n}_{0} , {n}_{1} , {n}_{2} ] , 0 \}\end{matrix} & if f = 3\end{matrix} \qquad Equation ( 43 )$$

The Equation (44) for m when p=0 is provided below, in contrast to Equation (37).

$$m = \{ \begin{matrix}\{ 0 \} & if f = 0 \\ \{ {M}^{8} [ {n}_{0} ] , {M}^{7} [ {n}_{0} ] , 0 \} & if f = 1 \\ [ , {M}^{8} [ {n}_{0} , {n}_{1} ] , {M}^{7} [ {n}_{0} , {n}_{1} ] , 0 \} & if f = 2 \\ \{ {\ddot{M}}^{8} [ {n}_{0} , {n}_{1} , {n}_{2} ] , {\ddot{M}}^{7} [ {n}_{0} , {n}_{1} , {n}_{2} ] , {M}^{8} [ {n}_{0} , {n}_{1} , {n}_{2} ] , {M}^{7} [ {n}_{0} , {n}_{1} , {n}_{2} ] , 0 \} & if f = 3\end{matrix} \qquad Equation ( 44 )$$

The equations (45) and (46) for K and d are provided below, in contrast to equations (38) and (41).

$$K = \{ \begin{matrix}1 & when f + p = 0 \\ 254 & when f + p = 1 \\ 78 & when f + p = 2 \\ 190 & when f + p = 3 \\ 70 & when f + p = 4\end{matrix} \qquad Equation ( 45 )$$

$$d = \{ \begin{matrix}\{ {\{ 0 \}}_{1} \} & when f + p = 0 \\ \{ {\{ 7 \}}_{253} , {\{ 1 \}}_{1} \} \} & when f + p = 1 \\ \{ {\{ 6 \}}_{77} , {\{ 2 \}}_{1} \} & when f + p = 2 \\ \{ {\{ 7 \}}_{168} , {\{ 5 \}}_{21} , {\{ 3 \}}_{1} \} & when f + p = 3 \\ \{ {\{ 6 \}}_{64} , {\{ 4 \}}_{6} \} & when f + p = 4\end{matrix} \qquad Equation ( 46 )$$

The remaining equations for the process of soft-decision Golay (24,12) decoder in the prior section remain unmodified. These alternative equations for the Golay (24,12) decoder can decrease the decoder performance by a negligible amount, while the complexity is reduced significantly. The complexity versus performance tradeoff is considered to select either of the processes according to the specific applications.

### Process of Soft-Decision Hamming (15,11) Decoder

The process of the soft-decision Hamming (15,11) decoder is quite similar to the processes of Golay decoder, while the process of the soft-decision Hamming decoder is less complex.

The input to the soft-decision Hamming (15,11) decoder is R, which includes B separate 15-bit codewords, denoted R_{B-1} through R₀, where B is the number of bits per soft-decision bit. R_{B-1} is the most significant codeword.

The first step in the process of soft-decision Hamming (15,11) decoder is to Hamming (15,11) decode the hard-decision codeword included in R_{B-1} to generate a corrected codeword W according to Equation (47). Additional codeword candidates that are “near” W will be evaluated by the soft-decision algorithm.]

$$W = h {d}^{15 , 11} ( {R}_{B - 1} ) \qquad Equation ( 47 )$$

Next, δ, the binary difference between R_{B-1} and W is computed.

$$δ = W - {R}_{B - 1} \qquad Equation ( 48 )$$

δ is a 15-bit value, which has a 1 in any bit position that was flipped by the Hamming decoder to obtain W from R_{B-1}. The hard-decision Hamming Decoder can correct only 1-bit error; thus, it can flip either 0 or 1 bits to obtain W from R_{B-1}. Next, f, the number of bits that were flipped by the Hamming decoder to obtain W from R_{B-1} is calculated via the following Equation (49).

$$f = c n {t}^{15} ( δ ) \qquad Equation ( 49 )$$

The difference is a binary difference, and the cnt¹⁵(x) function computes a sum of 15 bits to generate a Hamming weight. The Hamming (15,11) decoder can always flip 0 or 1 bits of the input to obtain the valid codeword nearest to the input. Thus, 0≤f≤1. When f is 0, the hard-decision Hamming decoder determined that the input codeword is valid and did not flip any bits. When f is 1, the hard-decision Hamming decoder flipped a single bit to obtain W from R_{B-1}, and the position of the bit flipped is an integer in the range of 0 to 14. This position is denoted n₀.

After computing f and no, a set of masks, m, is computed according to Equation (50).

$$m = \{ \begin{matrix}\{ 0 \} & when f = 0 \\ \{ {H}^{4} [ {n}_{0} ] , {H}^{3} [ {n}_{0} ] , 0 \} & when f = 1\end{matrix} \qquad Equation ( 50 )$$

The length of the set of masks, m, is denoted by K, which is computed according to Equation (51).

$$K = \{ \begin{matrix}1 & when f = 0 \\ 36 & when f = 1\end{matrix} \qquad Equation ( 51 )$$

Next, each mask in set m is applied to codeword W to obtain c, which includes a set of K codeword candidates according to Equation (52).

$${c}_{k} = W + {m}_{k} for 0 \leq k < K \qquad Equation ( 52 )$$

The hard-decision distance, between R_{B-1} and each codeword candidate, cₖ, is computed according to Equation (53).

$$d = \{ \begin{matrix}\{ {\{ 0 \}}_{1} \} & when f = 0 \\ \{ {\{ 3 \}}_{28} , {\{ 2 \}}_{7} , {\{ 1 \}}_{1} \} & when f = 1\end{matrix} \qquad Equation ( 53 )$$

Where the notation {a}_{b} is a vector including b repetitions of member a. These distances are generated without the use of a Hamming weight function. A set of soft-decision distances is computed for every codeword candidate in set c according to Equation (54).

$${\dot{d}}_{k} = {2}^{B - 1} \cdot {d}_{k} + {\sum }_{b = B - 2}^{0} {2}^{b} \cdot {cnt}^{15} ( {c}_{k} - {R}_{b} ) for 0 \leq k < K \qquad Equation ( 54 )$$

Equation (54) generates a set of distances that compensate for the soft-decision confidence of every bit in the received codeword, R.

The codeword from set c that generates the lowest soft-decision distance, \dot{d}ₖ, is selected as the output from the soft-decision Hamming (15,11) decoder. In some implementations, the N best outputs, rather than a single output codeword, are generated.

A confidence metric can be calculated when N>1. The confidence metric is the difference between the best distance and the second-best distance. As to hard-decision and no bit errors, two different Hamming codes differ in at least 3-bit positions. When there are no bit errors, the best distance is 0 and the second-best distance is 3.

### Process of Soft-Decision Block Decoder

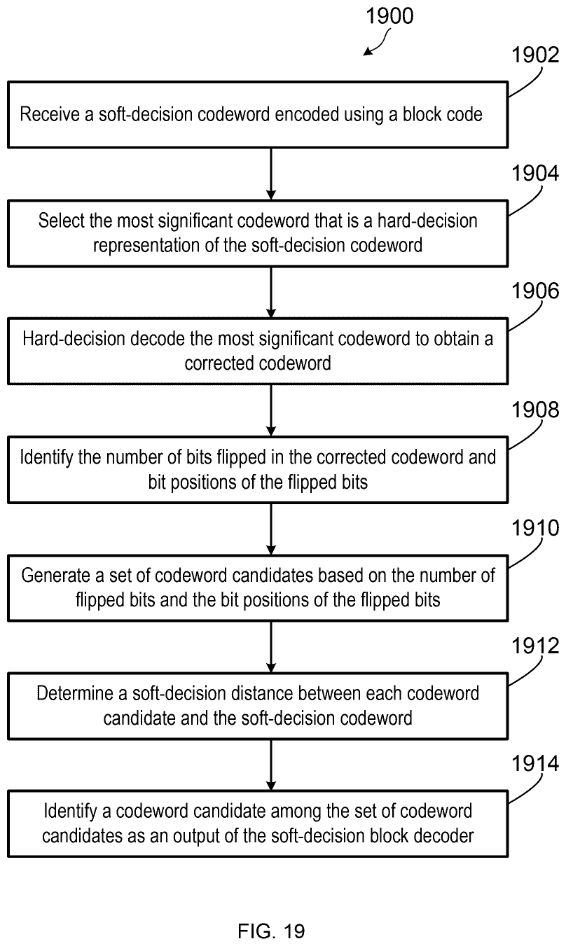

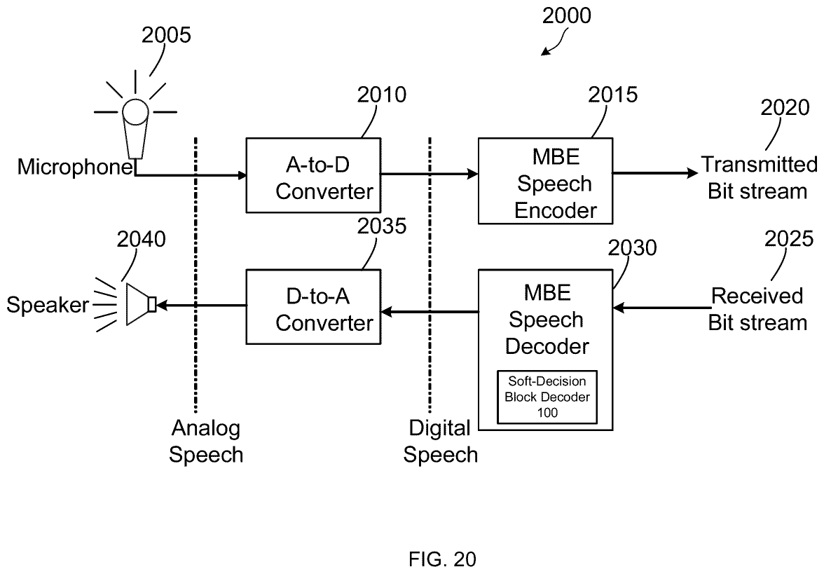

FIG. 19 is a flowchart of a process of soft-decision decoding a block code. The process 1900 can be implemented by a soft-decision block decoder (e.g., soft-decision block decoder 100 of FIG. 1), which can be a part of MBE speech decoder 2030 of FIG. 20 described later. The soft-decision block decoder 100 can be implemented by one or more processors or microcontrollers.

At 1902, the soft-decision block decoder receives a soft-decision codeword (e.g., R) encoded using the block code (e.g., a Golay (23,12) code, a Golay (24,12) code or a Hamming code). The soft-decision codeword (e.g., R) includes a plurality of codewords (e.g., R_{B-1} through R₀). The plurality of codewords (e.g., R_{B-1} through R₀) at least includes a least significant codeword (e.g., R₀) and a most significant codeword (e.g., R_{B-1});

At 1904, the soft-decision block decoder selects the most significant codeword (e.g., R_{B-1}) that is a hard-decision representation of the soft-decision codeword (e.g., R).

At 1906, the soft-decision block decoder hard-decision decodes (e.g., by hard-decision block decoder 105 of FIG. 1) the most significant codeword (e.g., R_{B-1}) to obtain a corrected codeword (e.g., W).

At 1908, the soft-decision block decoder identifies (e.g., by Hamming distance calculator 110 and bit position checker 115 of FIG. 1) the number (e.g., f) of bits flipped in the corrected codeword (e.g., W) and bit positions (e.g., n₀ through n_{f-1}) of the flipped bits based on a difference between the most significant codeword (e.g., R_{B-1}) and the corrected codeword (e.g., W). The number (e.g., f) of flipped bits is also equal to a Hamming distance between R_{B-1} and W.

At 1910, the soft-decision block decoder generates (e.g., by codeword candidate generator 120 of FIG. 1) a set of codeword candidates (e.g., cₖ) based on the number (e.g., f) of flipped bits and the bit positions (e.g., n₀ through n_{f-1}) of the flipped bits. The codewords are generated by choosing the subset of codewords that simultaneously satisfy two constraints: (i) the distance between each codeword candidate (e.g., cₖ) and the corrected codeword (e.g., W) is less than a first threshold and (ii) the distance between each codeword candidate (e.g., cₖ) and the most significant received codeword (e.g., R_{B-1}) is less than a second threshold. The first threshold is larger than the second threshold.

For a Golay (23,12) code, each codeword candidate has a distance of 8 (the first threshold) or less from the corrected codeword (e.g., W) and each codeword candidate (e.g., cₖ) also has a distance of 6 (the second threshold) or less from the most significant received codeword (e.g., R_{B-1}). There are 78 or fewer codeword candidates that satisfy both constraints. For a Golay (24,12) code, each codeword candidate (e.g., cₖ) has a distance of 8 or less from the corrected codeword (e.g., W) and each codeword candidate (e.g., cₖ) also has a distance of 8 (or 7 for a reduced complexity variant) or less from the most significant received codeword (e.g., R_{B-1}). There are 420 (or 254 for the reduced complexity variant) or fewer codeword candidates that satisfy both constraints. For a Hamming (15,11) code, each codeword candidate (e.g., cₖ) has a distance of 4 or less from the corrected codeword (e.g., W) and also has a distance of 3 or less from the most significant received codeword (e.g., R_{B-1}). There are 36 or fewer codeword candidates that satisfy both constraints.

At 1912, the soft-decision block decoder determines (e.g., by soft-decision distance calculator 125 of FIG. 1) a soft-decision distance (e.g., \dot{d}ₖ) between each codeword candidate (e.g., cₖ) and the soft-decision codeword (e.g., R).

To determine the soft-decision distance (e.g., \dot{d}ₖ), the soft-decision block decoder computes a Hamming distance between each of the plurality of codewords (e.g., R_{B-1} through R₀) and the candidate codeword (e.g., cₖ) and computes a weighted sum of the Hamming distances. A weight associated with the least significant codeword (e.g., R₀) is one (2⁰), and a weight (2^{b}, 0≤b<B) associated with a successively more significant codeword is twice a weight associated with an immediate previous codeword. A weight associated with the most significant codeword (e.g., R_{B-1}) is 2^{B-1}.

For example, the soft-decision codeword (e.g., R) can be divided into multiple codewords R₄, R₃, R₂, R₁, and R₀). R₄ is the most significant codeword and R₀ is the least significant codeword. The weight of R₀ is 1, the weight of R₁ is 2, the weight of R₂ is 4, the weight of R₁ is 8, and the weight of R₄ is 16. A candidate codeword is c. The soft-decision distance d=16×(R₄-c)+8×(R₃-c)+4×(R₂-c)+2×(R₁-c)+1×(R₀-c). R₄-c is a Hamming distance between the candidate codeword c and R₄, R₃-c is a Hamming distance between the candidate codeword c and R₃, R₂-c is a Hamming distance between the candidate codeword c and R₂, R₁-c is a Hamming distance between the candidate codeword c and R₁, and R₀-c is a Hamming distance between the candidate codeword c and R₀.

At 1914, the soft-decision block decoder identifies (e.g., by soft-decision distance calculator 125 of FIG. 1) a codeword candidate among the set of codeword candidates (e.g., cₖ) as an output of the soft-decision block decoder, wherein the codeword candidate has the lowest soft-decision distance (e.g., \dot{d}ₖ).

In some implementations, the most significant codeword (e.g., R_{B-1}) includes the most significant bit (MSB) of each soft-decision bit in the soft-decision codeword (e.g., R).

In some implementations, the number (e.g., f) of the flipped bits is associated with a type of the block code, and the type of the block code is a Golay (23,12) code, a Golay (24,12) code or a Hamming code.

In some implementations, to generate the set of codeword candidates, the soft-decision block decoder generates one or more subsets of masks

$$( e . g . , {M}_{k}^{7} , {M}_{k}^{8} )$$

based on the number (e.g., f) of flipped bits and a type of the block code, and applies the one or more

$$( e . g . , {M}_{k}^{7} , {M}_{k}^{8} )$$

to the corrected codeword (e.g., W) to obtain the set of codeword candidates (e.g., cₖ). The subsets of masks

$$( e . g . , {M}_{k}^{7} , {M}_{k}^{8} )$$

are generated so that two distance constraints described at 1910 are satisfied. The subsets of masks

$$( e . g . , {M}_{k}^{7} , {M}_{k}^{8} )$$

are generated using equations (24), (36), (37), (43), (44), and (50). For example, to generate a set of codeword candidates for Golay (23,12), a subset of masks in M⁷ and M⁸ are produced, where M⁷ includes 253 masks and M⁸ includes 506 masks. M⁷ includes masks that have a Hamming weight of 7 and M⁸ includes masks that have a Hamming weight of 8. The masks are used to generate codeword candidates having a distance of 7 or 8 from the corrected codeword (e.g., W). The codeword candidate generator 120 identifies a subset of these masks such that the distance between the most significant codeword the most significant codeword (e.g., R_{B-1}) and each codeword candidate is less than or equal to 6. The number of codeword candidates in this subset is less than or equal to 78.

In some implementations, M⁷ is a set of masks defined by producing 23-bit rotations of every mask in the set {0x00c75, 0x0254b, 0x05e09, 0x081b3, 0x0a88d, 0x14585, 0x1c843, 0x21253, 0x26911, 0x320e1, 0x46245}, such that the total number of masks in the set is 253 and each mask in the set has a Hamming weight of 7. M⁸ is a set of masks defined by producing 23-bit rotations of every mask in the set {0x0149f, 0x03da1, 0x046e3, 0x09959, 0x0b067, 0x0cb25, 0x0e21b, 0x10f13, 0x1262d, 0x17451, 0x182d5, 0x1d0a9, 0x20ab9, 0x22387, 0x258c5, 0x31135, 0x34349, 0x428d3, 0x45391, 0x48c2b, 0x4a515, 0x66489}, such that the total number of masks in the set is 506 and each mask in the set has a Hamming weight of 8. The codeword candidate generator 120 generates the following codeword candidates, such that every codeword candidate has a distance between each codeword candidate and the most significant codeword (e.g., R_{B-1}) that is less than or equal to 6.

When f is 0, the only codeword candidate that satisfies both constraints is W itself (1 codeword candidate with a distance of 0), such that when f is 0 the total number of codeword candidates is 1.

When f is 1, the codeword candidates that satisfy both constraints are: (i) W itself (1 codeword candidate with a distance of 1); and (ii) W xored with a subset of masks from M⁷ that have a one (a value of “1”) at bit n₀ (77 codeword candidates with a distance of 6), such that when f is 1, the total number of codeword candidates is 78.

When f is 2, the codeword candidates that satisfy both constraints are: (i) W itself (1 codeword candidate with a distance of 2); (ii) W xored with a subset of masks from M⁸ that have a one (a value of “1”) at both bits n₀ and n₁ (56 codeword candidates with a distance of 6); and (iii) W xoredwith a subset of masks from M⁷ that have a one (a value of “1”) at both bits n₀ and n₁ (21 codeword candidates with a distance of 5), such that when f is 2, the total number of codeword candidates is 78.

When f is 3, the codeword candidates that satisfy both constraints are: (i) W itself (1 codeword candidate with a distance of 3); (ii) W xored with a subset of masks from M⁷ that have a one in exactly 2 of the 3 bit-positions {n₀, n₁, n₂} (48 codeword candidates with a distance of 6); (iii) W xored with a subset of masks from M⁸ that have a one (a value of “1”) at all 3 bit-positions {n₀, n₁, n₂} (16 codeword candidates with a distance of 5), and (iv) W xored with a subset of masks from M⁷ that have a one (a value of “1”) at all 3 bit-positions {n₀, n₁, n₂} (5 codeword candidates with a distance of 4), such that when f is 3, the total number of codeword candidates is 70.

In some implementations, to apply each set of masks

$$( e . g . , {M}_{k}^{7} , {M}_{k}^{8} )$$

to the most significant codeword (e.g., R_{B-1}), the soft-decision block decoder performs an Exclusive-OR operation for each set of masks

$$( e . g . , {M}_{k}^{7} , {M}_{k}^{8} )$$

and the set of codeword candidates (e.g., cₖ).

In some implementations, to determine the soft-decision distance (e.g., \dot{d}ₖ), the soft-decision block decoder determines a hard-decision distance (e.g., d) between the most significant codeword (e.g., R_{B-1}) and each codeword candidate (e.g., cₖ) based on the number (e.g., f) of flipped bits, and determines the soft-decision distance (e.g., \dot{d}ₖ) between each codeword candidate (e.g., cₖ) and the soft-decision codeword (e.g., R) using the hard-decision distance (e.g., d).

In some implementations, to determine the soft-decision distance (e.g., \dot{d}ₖ), the soft-decision block decoder sums a distance between each bit of soft-decision codeword (e.g., R) and the corresponding bit in the corrected codeword (e.g., W).

In some implementations, to determine the soft-decision distance (e.g., \dot{d}ₖ), the soft-decision block decoder determines a Hamming weight (e.g., L-bit Hamming weight, cnt^{L}(Rₚ−W)) of a difference between the corrected codeword (e.g., W) and the soft-decision codeword (e.g., R) and determines the soft-decision distance (e.g., \dot{d}ₖ) using the Hamming weight (e.g., L-bit Hamming weight, cnt^{L}(R_{b}−W)).

In some implementations, codeword candidate generation and selection can be skipped or bypassed when there are very few bit errors. The soft-decision block decoder determines a soft-decision distance (e.g., D) between the corrected codeword (e.g., W) and the soft-decision codeword (e.g., R), and determines the corrected codeword (e.g., W) as the output of the soft-decision block decoder based on the soft-decision distance (e.g., D) between the corrected codeword (e.g., W) and the soft-decision codeword (e.g., R) being less than or equal to a particular threshold (e.g., D≤381/2^{7-B}).

In some implementations, common codewords in the soft-decision codeword R can be eliminated to remove redundancy. For example, there are three same codewords in the soft-decision codeword R, only one codeword is kept while the other two same codewords are eliminated or removed from the soft-decision codeword R. The soft-decision codeword (e.g., R) includes a set of first codewords. The soft-decision block decoder eliminates one or more first codewords from the set of first codewords and each of the one or more first codewords has a common or same first codeword in the set.

The soft-decision block decoder and the process 1900 described herein can be implemented in a speech decoder, a handset or mobile radio device, a base station or console, or a wireless communication device, etc.

### Optional Techniques to Further Reduce Soft-Decision Block Decoder Complexity

In some implementations, a few optional techniques can further improve the soft-decision block decoders described previously.

Bypass Codeword Candidate Generation and Selection when Codeword W has Low Distance

In some implementations, the candidate evaluation is bypassed, which can significantly reduce the average number of cycles used to perform a soft-decision block decoding using the processes previously described for decoding Golay (12,23), Golay (12,24), and Hamming (15,11) codes. As to low bit error rates, the codeword W, generated by the hard-decision decoder is the best candidate. In fact, when there are no bit errors, the hard-decision block decoder generates the correct result. Prior to generating K candidates for the soft-decision decoder, the following distance can be evaluated according to Equation (55).

$$D = {\sum }_{b = B - 1}^{0} {2}^{b} \cdot {cnt}^{15} ( W - {R}_{b} ) \qquad Equation ( 55 )$$

Equation (55) evaluates the soft-decision distance for the codeword generated by the hard-decision decoder.

As to the Golay (23,12) and Golay (24,12) decoders, when D≤381/2^{7-B}, the codeword search can be bypassed, and the hard-decision result can be accepted without evaluating the distances of K codeword candidates. As to the Hamming (15,11) decoder, the corresponding threshold is D≤381/2^{7-B}. Bypassing all the candidate evaluation greatly reduces the number of cycles consumed for low bit error rates, and thus also reduces power consumed. The thresholds can be adjusted so that bypassing does not impact decoding performance. The candidate evaluation is bypassed only when D is low enough to guarantee that codeword W is the best candidate.

### Common Codeword Elimination

As described previously, the received B-bit soft-decision codeword, R, is received in the form of B L-bit codewords. The individual codewords are denoted, R_{b} for 0≤b<B. The associated weight of each such codeword in the distance equation is 2^{b}. It is likely that two individual codewords R_{b} are identical. As an ideal input, where all bits are received with the highest possible confidence, R_{b} is identical for all values of B. It is possible to replace R_{b} for 0≤b<B with R_{f} for 0≤f<F, where F≤B, such that no codewords in R_{f} are identical. To eliminate common codewords without impacting the distance equation, the weights of the common codewords in R_{b} can be combined or summed. If the weights associated with B codewords are denoted Wₚ=2^{b} for 0≤b<B, a new set of weights W_{f} for 0≤f<F can be computed. The new set of weights W_{f} combines the associated weights of codewords that are merged when removing the common codewords.

For example, the soft-decision codeword (e.g., R) can be divided into multiple codewords R₄, R₃, R₂, R₁, and R₀). R₄ is the most significant codeword and R₀ is the least significant codeword. The weight of R₀ is 1, the weight of R₁ is 2, the weight of R₂ is 4, the weight of R₁ is 8, and the weight of R₄ is 16. If R₄ and R³ are identical, R₃ is eliminated. Weights for R₄, R₂, R₁, and R₀ are 24 (i.e., 8+16), 4, 2, 1, respectively. If R₀ and R₂ are identical, R₀ is eliminated. Weights for R₄, R₃, R₂, R₁ are 16, 8, 5 (i.e., 4+1), 2, respectively.

Accordingly, the distance equation (56) is provided below.

$${\dot{d}}_{k} = {W}_{F - 1} \cdot {d}_{k} + {\sum }_{f = F - 2}^{0} {W}_{F - 1} \cdot {cnt}^{L} ( {c}_{k} - {R}_{f} ) \qquad Equation ( 56 )$$

$$for 0 \leq k < K$$

Since F≤B, equation (56) can lead to reduced complexity, especially when F is much lower than B. For example, when the input is an ideal input, F is much lower than B, which leads to lower complexity due to the elimination of common codewords.

### Elimination of Codeword Candidates in Multiple Stages to Reduce Complexity

The computation complexity of processes of a soft-decision block decoder described previously is determined based on the equation that evaluates a soft-decision distance for every codeword candidate. The number of computation cycles is proportional to both F, the number of unique codewords in R, and the number of codeword candidates K. It is possible to partially evaluate the distance equation over a smaller range of f, eliminate candidates that have a partial distance greater than a threshold, and then continue to evaluate the distances for the surviving candidates over a wider range of f. In this way, codeword candidates can be eliminated in one or more stages, with different distance thresholds for each stage. In some implementations, it is preferred to evaluate larger values of f first, since they have the highest weight. This technique is particularly beneficial for the Golay (24,12) decoder since the value for K is large.

### Application of Processes of Soft-Decision Block Decoder

The processes described can be used to reduce the complexity of Project 25 Full-Rate Error Control Decoder, e.g., as described in U.S. patent application Ser. No. 18/482,350, filed on Oct. 6, 2023, entitled “BIT ERROR CORRECTION IN DIGITAL SPEECH,” which is incorporated herein in its entirety. The soft-decision Golay decoders as described in the U.S. patent application Ser. No. 18/482,350 (referring to equations (10)-(15) and (24)-(26)) are close derivatives of a Maximum Likelihood decoder and can be replaced with a lower complexity soft-decision Golay decoder described herein. Similarly, the soft-decision Hamming decoders as described in the U.S. patent application Ser. No. 18/482,350 (referring to equations (16)-(21)) are also close derivatives of the Maximum Likelihood decoder and can be replaced with a lower complexity soft-decision Hamming decoder described herein. Application of these reduced complexity soft-decision decoders (lower complexity soft-decision Golay decoder and soft-decision Hamming decoder) can result in a substantial reduction in complexity, with little impact on performance.

Additional complexity improvement can be achieved by eliminating equations (2)-(6) in the U.S. patent application Ser. No. 18/482,350 and generating codewords ċⁿ and D_{0,n} with codewords and the associated distances provided by the Golay decoder described herein. The Golay decoder described herein can generate N best codeword candidates, rather than just a single best codeword. The Golay decoder can evaluate soft-decision distances for the K codeword candidates, and eliminate all but the N candidates that generate the N lowest distances. Thus, c for 0≤j<23 forms the input soft-decision codeword to the Golay decoder. It can be converted from a series of 23 B-bit soft-decision bits, to a series of B 23-bit codewords. The Golay decoder then generates K codeword candidates, evaluates soft-decision distances for each of them, and narrows the codewords down to N codewords having the lowest soft-decision distance from the received codeword. The N best codewords form ċⁿ for 0≤n<N and the corresponding distances form D_{0,n} for 0≤n<N. N_{c}, as described in paragraph of the U.S. patent application Ser. No. 18/482,350, is replaced by N.

The decoding performance increases as Nis increased, while the rate of performance gain diminishes as N increases. For example, N=2 achieves significantly better performance than N=1. N=3, produces slightly better decoding performance than N=2. Performance continues to increase as N increases, but the rate of performance increase rapidly diminishes. The complexity of the decoder is approximately proportional to N, and thus an appropriate performance versus complexity tradeoff is considered. The processes described herein achieve improved efficiency over the process described in the U.S. patent application Ser. No. 18/482,350, such that N_{c} in the U.S. patent application Ser. No. 18/482,350, has to be significantly greater than N, to achieve the same performance of the processes described herein.

Similar substitutions can be made to the Project 25. Half-Rate Error Control Decoder as described in the U.S. patent application Ser. No. 18/482,350. The Golay decoders described in the U.S. patent application Ser. No. 18/482,350 are close derivatives of Maximum Likelihood decoders and can be replaced with a reduced complexity decoder provided herein. In addition, the candidates for the first codeword can be generated in a simplified way as described above for the Project 25. Full Rate Error Control Decoder.

The techniques may be implemented with software. For example, the techniques may be implemented by a speech decoder in a vocoder that is included in, for example, a mobile radio device or a cellular telephone. FIG. 20 illustrates a block diagram of a vocoder 2000 that samples analog speech or some other signal from a microphone 2005. An analog-to-digital (“A-to-D”) converter 2010 digitizes the sampled speech to produce a digital speech signal. The digital speech signal is processed by an MBE speech encoder 2015 to produce a digital bit stream 2020 suitable for transmission or storage. The speech encoder 2015 processes the digital speech samples in short frames. Each frame of digital speech samples produces a corresponding frame of bits in the bit stream output of the speech encoder 2015.

FIG. 20 further depicts a received bit stream 2025 entering an MBE speech decoder 2030 that processes each frame of bits to produce a corresponding frame of synthesized speech samples. A digital-to-analog (“D-to-A”) converter 2035 then converts the digital speech samples to an analog signal that can be passed to a speaker 2040 for conversion into an acoustic signal suitable for human listening. The soft-decision block decoder 100 of FIG. 1 is implemented in the MBE speech decoder 2030.

Any of the above-described examples may be combined with any other example (or combination of examples), unless explicitly stated otherwise. The foregoing description of one or more implementations provides illustration and description, but is not intended to be exhaustive or to limit the scope of implementations to the precise form disclosed. Modifications and variations are possible in light of the above teachings or may be acquired from practice of various implementations.

Although the implementations above have been described in considerable detail, numerous variations and modifications will become apparent to those skilled in the art once the above disclosure is fully appreciated. It is intended that the following claims be interpreted to embrace all such variations and modifications.

We claim:

1. A method of soft-decision decoding a block code implemented by a soft-decision block decoder, the method comprising:
receiving a soft-decision codeword encoded using the block code, wherein the soft-decision codeword comprises a plurality of codewords that at least comprise a most significant codeword that is a hard-decision representation of the soft-decision codeword and a least significant codeword;
hard-decision decoding the most significant codeword to obtain a corrected codeword;
identifying the number of bits flipped in the corrected codeword and bit positions of the flipped bits based on a difference between the most significant codeword and the corrected codeword;
generating a set of codeword candidates based on the number of flipped bits and the bit positions of the flipped bits, wherein the set of codeword candidates are closest to the corrected codeword, a distance between each candidate codeword and the corrected codeword is less than a first threshold, and a distance between each candidate codeword and the most significant codeword is less than a second threshold;
determining a soft-decision distance between each codeword candidate and the soft-decision codeword; and
identifying a codeword candidate from among the set of codeword candidates that has the lowest soft-decision distance as an output of the soft-decision block decoder.

2. The method of claim 1, wherein the most significant codeword includes the most significant bit (MSB) of each soft-decision bit in the soft-decision codeword.

3. The method of claim 1, wherein the number of the flipped bits is associated with a type of the block code, and the type of the block code is a Golay (23,12) code, a Golay (24,12) code, or a Hamming code.

4. The method of claim 1, wherein generating the set of codeword candidates comprises:
generating one or more sets of masks based on the number of flipped bits and a type of the block code; and
applying the one or more sets of masks to the most significant codeword to obtain the set of codeword candidates.

5. The method of claim 4, wherein applying each set of masks to the most significant codeword comprises Exclusive-ORing (XORing) each set of masks with the set of codeword candidates.

6. The method of claim 1, wherein determining the soft-decision distance comprises:
computing a Hamming distance between each of the plurality of codewords and a candidate codeword, wherein each of the plurality of codewords is associated with a different weight; and
computing a weighted sum of the Hamming distances.

7. The method of claim 6, wherein a weight associated with the least significant codeword is one, and a weight associated with a successively more significant codeword is twice a weight associated with an immediately previous codeword.

8. The method of claim 7, further comprising:
identifying at least two identical codewords from the plurality of codewords;
summing weights associated with the two identical codewords; and
eliminating at least one identical codeword, so that no codewords are identical in the plurality of codewords.

9. The method of claim 1, wherein the first threshold is larger than the second threshold.

10. A soft-decision block decoder configured to perform the method of claim 1.

11. A handset or mobile radio device comprising the soft-decision block decoder of claim 10.

12. A base station or console comprising the soft-decision block decoder of claim 10.

13. A wireless communication device comprising the soft-decision block decoder of claim 10.

14. A method of soft-decision decoding a block code implemented by a soft-decision block decoder, the method comprising:
receiving a soft-decision codeword encoded using the block code, wherein the soft-decision codeword comprises a plurality of codewords that at least comprise a most significant codeword that is a hard-decision representation of the soft-decision codeword and a least significant codeword;
hard-decision decoding the most significant codeword to obtain a corrected codeword;
determining a soft-decision distance between the corrected codeword and the soft-decision codeword; and
determining the corrected codeword as an output of the soft-decision block decoder based on the soft-decision distance between the corrected codeword and the soft-decision codeword being less than or equal to a particular threshold.

15. A soft-decision block decoder configured to perform the method of claim 14.

16. A handset or mobile radio device comprising the soft-decision block decoder of claim 15.

17. A base station or console comprising the soft-decision block decoder of claim 15.

18. A wireless communication device comprising the soft-decision block decoder of claim 15.
